(19) United States
(12) Patent Application Publication
(10) Pub. No.: US 2014/0131684 A1
(43) Pub. Date: May 15, 2014

(54) ELECTRONIC DEVICE HAVING RADIATION-PRODUCED CONTAINMENT REGIONS AND PROCESSES FOR MAKING SAME

(71) Applicant: E I DU PONT DE NEMOURS AND COMPANY, Wilmington, DE (US)

(72) Inventors: Shiva Prakash, Santa Barbara, CA (US); Stephen Sorich, Goleta, CA (US); Adam Fennimore, Wilmington, DE (US)

(73) Assignee: E I DU PONT DE NEMOURS AND COMPANY, Wilmington, DE (US)

(21) Appl. No.: 14/075,040

(22) Filed: Nov. 8, 2013

Related U.S. Application Data
(60) Provisional application No. 61/726,122, filed on Nov. 14, 2012.
(60) Provisional application No. 61/726,127, filed on Nov. 14, 2012.
(60) Provisional application No. 61/726,130, filed on Nov. 14, 2012.
(60) Provisional application No. 61/726,148, filed on Nov. 14, 2012.

(51) Int. Cl. H01L 51/05; H01L 51/00

(52) U.S. Cl. CPC H01L 51/05; H01L 51/0001
USPC 257/40; 438/99

(57) ABSTRACT

An electronic device includes a backplane having a layer of an organic hole injection material disposed thereon. Some areas of the hole injection material having a first predetermined surface energy while selected other areas of the layer of hole injection material have a second, lower, predetermined surface energy associated therewith. The selected other areas of lower surface energy are produced by heating of these areas by exposure of the selected other areas to radiation, such as from a laser. A layer of a composition including an organic hole transport material disposed directly on at least some of the areas of the layer of the hole injection material having the first, higher, predetermined surface energy.

### CROSS REFERENCE TO RELATED APPLICATIONS

The present application claims the benefit of provisional patent application Ser. Nos. 61/726,130, 61/726,122, 61/726,148, and 61/726,127, all filed on Nov. 14, 2013.

### BACKGROUND OF THE INVENTION

1. Field of the Invention

This invention relates to an electronic device in which radiation, such as from a laser, is used to produce regions of surface energy discontinuity that provide containment between adjacent display pixels (or subpixels) of the device and to methods for making such device.

2. Description of the Related Art

Organic electronic devices utilizing organic active materials are present in many different kinds of electronic equipment. The term “organic electronic device(s)” is(are) intended to mean device(s) including one or more layers of organic semiconductor materials sandwiched between two electrodes. An organic electronic device includes, but is not limited to: (1) a device that converts electrical energy into radiation (e.g., a light-emitting diode, a light emitting diode display, a diode laser, or a lighting panel); (2) a device that detects a signal using an electronic process (e.g., a photodetector, a photoconductive cell, a photoresistor, a photoswitch, a phototransistor, a phototube, an infrared (“IR”) detector, or a biosensor); (3) a device that converts radiation into electrical energy (e.g., a photovoltaic device or solar cell); (4) a device that includes one or more electronic components that include one or more organic semiconductor layers (e.g., a transistor or diode); or any combination of devices in items (1) through (4).

One type of organic electronic device is an organic light emitting diode (OLED). OLEDs are promising for display applications due to their high power-conversion efficiency and low processing costs. Such displays are especially promising for battery-powered, portable electronic devices, including cell-phones, personal digital assistants, handheld personal computers, and DVD players. These applications call for displays with high information content, full color, and fast video rate response time in addition to low power consumption.

For the manufacture of a full-color OLED display, each pixel of the display is typically divided into three subpixels, each emitting one of the three primary display colors: red, green, and blue. (In some cases only two or in other cases more than three subpixels may be created). Each of the subpixels receives a specific material that produces the respective color displayed by that subpixel.

Colored materials in liquid form are referred to as “colored inks.” During deposition it is important to contain the colored inks to avoid color mixing.

As used herein the term “contained,” or like terms, when referring to a material is intended to mean that as a colored ink is applied it does not spread significantly beyond the area where it is deposited despite a natural tendency to do so were it not contained.

Several techniques for providing containment for colored ink are known. With one technique, termed “physical containment,” the colored ink is contained by physical barrier structures. With another technique, termed “chemical containment,” the colored ink is contained by surface energy effects. A material may be contained by a combination of chemical containment and physical containment techniques.

Physical containment techniques involve the use of obstacles, such as elongated banks or pixel wells, that inhibit spreading of the colored ink. In order to be effective these structures must be large in the direction perpendicular to the surface on which they are deposited (i.e., their thickness), comparable to the wet thickness of the deposited materials. When the colored ink is printed into a subpixel, the ink wets onto the structure's surface so that thickness uniformity is reduced near the structure. Therefore, to compensate, the containment structure must be moved outside the emissive pixel or subpixel region so the non-uniformities are not visible in operation. Due to limited space on the display (especially high-resolution displays) this compensating action reduces the available emissive area of the pixel and is therefore perceived as disadvantageous. Physical containment structures generally have a negative impact on quality when depositing continuous layers of materials, e.g., the layers which do not emit color, such as charge injection and transport layers.

Chemical containment techniques involve the creation of surface energy discontinuities between areas desired to be segregated.

The term “surface energy” is the energy required to create a unit area of a surface from a material. A characteristic of surface energy is that a liquid material such as a colored ink having a given surface energy will not wet (i.e., spread onto) surfaces with a lower surface energy. Thus, if the surface energy of a surface is higher than that of the liquid, the liquid wets the surface.

Surface energy discontinuities may be produced by either printing or vapor-depositing regions of low surface energy materials onto the first organic active layer of the subpixel. These low surface energy materials generally are applied before printing or coating the first organic active layer in the subpixel area.

In view of the foregoing there is believed to be a need for an improved process for forming electronic devices, especially for an improved process of providing chemical containment of liquid colored inks.

### SUMMARY OF THE INVENTION

In some embodiments of the present invention, an electronic device includes a backplane and a layer of an first organic electro-active material (e.g., organic hole injection material) disposed on the backplane, with some areas of the layer of hole injection material having a predetermined first surface energy associated therewith while selected other areas of the layer of hole injection material have a predetermined second, lower, surface energy associated therewith. The selected other areas of lower surface energy are produced by heating of these areas by exposure of the selected other areas to radiation, such has that provided from a laser. The device also includes a layer of a second organic electro-active material (e.g., an organic hole transport material) disposed directly on at least some of the areas of the layer of the first organic electro-active material (e.g., hole injection material) having the first, higher, predetermined surface energy.

In some embodiments of the present invention, an electronic device includes a backplane and a layer of a first organic electro-active material (e.g., organic hole injection material) disposed on the backplane and a layer of sacrificial material disposed directly on the layer of the first organic electro-active material, some areas of the layer of sacrificial material having a first predetermined surface energy associated therewith while selected other areas of the layer of the sacrificial material have a second, lower, predetermined surface energy associated therewith. The selected other areas of lower surface energy being produced by exposure of the selected other areas to radiation, such has that provided from a laser. The device also includes a layer of a second organic electro-active material (e.g., an organic hole transport material) disposed directly on substantially all of the areas of the layer of the sacrificial material having the first predetermined surface energy.

In some embodiments of the present invention, a process for forming an electronic device having at least two organic electro-active materials disposed over a backplane includes depositing a first organic electro-active material on a backplane, the first organic electro-active material having a predetermined first surface energy associated therewith, exposing predetermined areas of the first electro-active material to radiation from a radiation source to heat the first electro-active material to an extent sufficient to cause the exposed areas to have a second surface energy lower than the first surface energy.

The process further includes depositing a liquid composition including a second electro-active material on the first electro-active material, the liquid composition having a predetermined third surface energy associated therewith such it preferentially wets the areas of the first electro-active material having the higher first surface energy to the substantial exclusion of the areas of the first electro-active material having the lower second surface energy.

In some embodiments of the present invention, a process for forming an electronic device having at least two organic electro-active materials disposed over a backplane includes depositing a first organic electro-active material on a backplane, the first organic electro-active material having a predetermined first surface energy associated therewith and depositing a sacrificial material directly on the first organic electro-active material, the sacrificial material having a predetermined second surface energy associated therewith, exposing predetermined areas of the sacrificial material to radiation from a radiation source to heat the sacrificial material and the first electro-active material to an extent sufficient to cause the exposed areas to have a surface energy lower than the surface energy of an adjacent unexposed area.

The process includes depositing a liquid composition including a second electro-active material directly on the sacrificial material, the liquid composition having a predetermined third surface energy associated therewith such it preferentially wets the areas having the higher surface energy to the substantial exclusion of the areas having the lower surface energy.

In some embodiments, the difference between the first surface energy and the second surface energy is sufficient to provide chemical containment for a liquid composition deposited directly on this first organic electro-active material.

In some embodiments the first electro-active material is a hole injection material that includes a conductive polymer and a fluorinated acid polymer. The sacrificial material is for example, a molybdenum oxide that is non-reactive with the hole injection material.

In some embodiments, the difference in surface energy between radiation-treated and non-treated areas, as measured by contact angle determined using of anisole as a test liquid, is at least twenty degrees (20°); in some embodiments the difference is at least twenty-five degrees (25°); in some embodiments the difference is at least thirty degrees (30°); and in some embodiments the difference is at least forty degrees)(40°).

### BRIEF DESCRIPTION OF THE DRAWINGS

The invention will be more fully understood from the following detailed description, taken in connection with the accompanying drawings, which form a part of this application and in which:

FIGS. 1A and 1B are highly stylized pictorial representations illustrating side sectional views of backplane structures used in the Prior Art and upon which an electronic device in accordance with the present invention may be fabricated;

FIGS. 2A and 2B are plan views taken along respective view lines 2A-2A in FIGS. 1A and 2B-2B in FIG. 1B:

FIGS. 3A through 3H are highly stylized pictorial representations illustrating side sectional views showing the structure of an electronic device fabricated on a backplane as shown in FIG. 1A at various stages during its fabrication using the process in accordance with embodiments of the present invention;

FIGS. 4A through 4H are highly stylized pictorial representations generally similar to FIGS. 3A through 3H illustrating side sectional views showing the structure of a slightly modified electronic device fabricated on a backplane as shown in FIG. 1A at various stages during its fabrication using the process in accordance with embodiments of the present invention;

FIGS. 5A through 5H are highly stylized pictorial representations illustrating side sectional views showing the structure of an electronic device fabricated on a backplane as shown in FIG. 1B at various stages during its fabrication using the process in accordance with embodiments of the present invention;

FIGS. 6A and 6B are process diagrams indicating the steps of processes for producing an electronic device in accordance with embodiments of the present invention;

FIG. 7 is highly stylized definitional drawing from which an understanding of the manner in which “contact angle” may be derived;

FIG. 8 is a graphical representation of a plot of contact angle as a function of temperature for the two test samples of the Examples; and

FIG. 9 is a stylized representation of a photomicrograph of deposited drops and irradiated line, as described in the Examples.

### DEFINITIONS

As used in this application the following terms have the meanings indicated:

The term “acid polymer” refers to a polymer having acidic groups.

The term “acidic group” refers to a group capable of ionizing to donate a hydrogen ion to a Brønsted base.

The term “charge transport,” when referring to a layer, material, member, or structure is intended to mean such layer, material, member, or structure facilitates migration of such charge through the thickness of such layer, material, member, or structure with relative efficiency and small loss of charge. Hole transport materials facilitate positive charge; electron transport materials facilitate negative charge. Although light-emitting materials may also have some charge transport properties, the term “charge transport layer, material, member, or structure” is not intended to include a layer, material, member, or structure whose primary function is light emission, detection, or absorption.

The term “doped”, as it refers to an electrically conductive polymer, is intended to mean that the electrically conductive polymer has a polymeric counterion to balance the charge on the polymer.

The term “doped electrically conductive polymer” is intended to mean the electrically conductive polymer and the polymeric counterion that is associated with it.

The term “electrically conductive” as it refers to a material, is intended to mean a material which is inherently or intrinsically capable of electrical conductivity without the addition of carbon black or conductive metal particles.

The term “fluorinated” refers to a compound in which one or more hydrogens bonded to carbon have been replaced by fluorine. The term “highly-fluorinated” refers to a compound in which at least 90% of the available hydrogens bonded to carbon have been replaced by fluorine. The terms “fully-fluorinated” and “perfluorinated” are used interchangeably and refer to a compound where all of the available hydrogens bonded to carbon have been replaced by fluorine.

The term “layer” is used interchangeably with the term “film” and refers to a coating covering a desired area. The term is not limited by size. The area can be as large as an entire device or as small as a specific functional area such as the actual visual display, or as small as a single sub-pixel. Layers and films can be formed by any conventional deposition technique, including vapor deposition, liquid deposition (continuous and discontinuous techniques), and thermal transfer.

The term “nanoparticle” refers to a material having a particle size less than 100 nm. In some embodiments, the particle size is less than 10 nm. In some embodiments, the particle size is less than 5 nm. The term “particle size” is used to indicate the maximum size of at least 90% of the particles.

The term “polymer” is intended to mean a material having at least one repeating monomeric unit. The term includes homopolymers having only one kind, or species, of monomeric unit, and copolymers having two or more different monomeric units, including copolymers formed from monomeric units of different species.

In this specification, unless explicitly stated otherwise or indicated to the contrary by the context of usage, where an embodiment of the subject matter hereof is stated or described as comprising, including, containing, having, being composed of or being constituted by or of certain features or elements, one or more features or elements in addition to those explicitly stated or described may be present in the embodiment. Where an alternative embodiment of the disclosed subject matter hereof is described as consisting essentially of certain features or elements, features or elements that would materially alter the principle of operation or the distinguishing characteristics of the embodiment are not present therein. A further alternative embodiment of the described subject matter hereof is described as consisting of certain features or elements, in which embodiment, or in insubstantial variations thereof, only the features or elements specifically stated or described are present.

Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

### DETAILED DESCRIPTION OF THE INVENTION

Throughout the following detailed description similar reference characters refers to similar elements in all figures of the drawings.

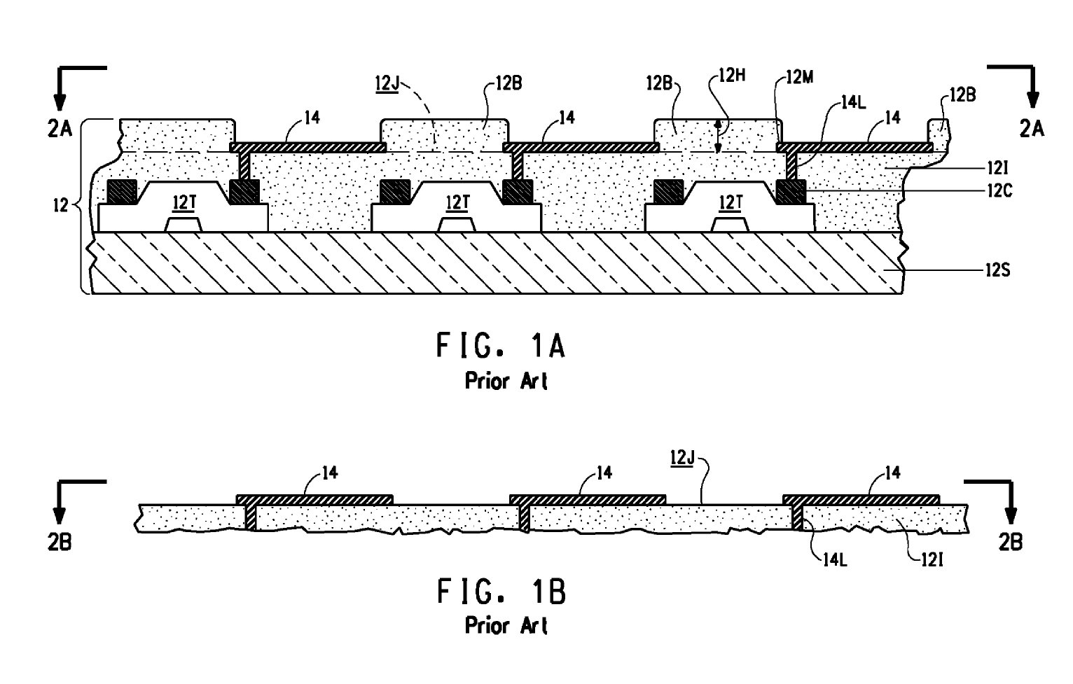

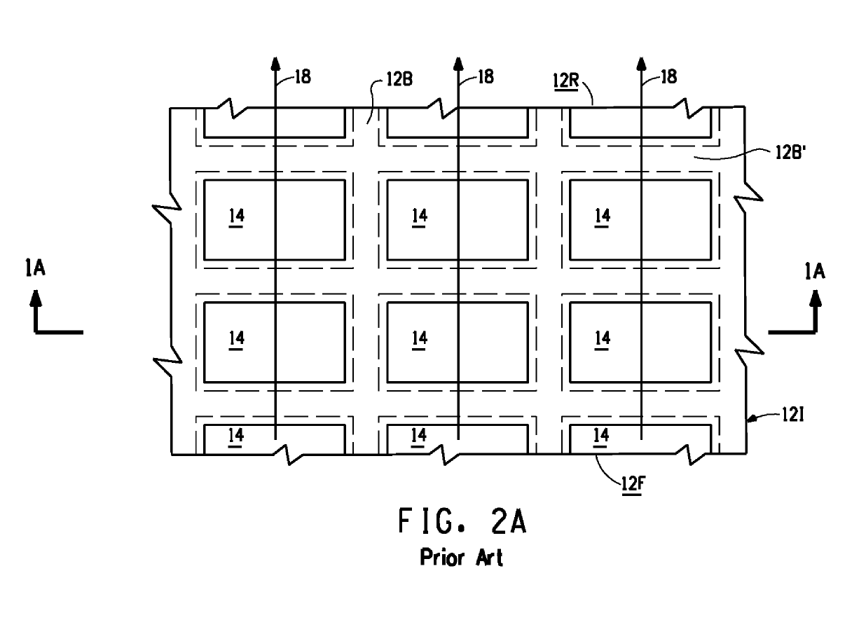

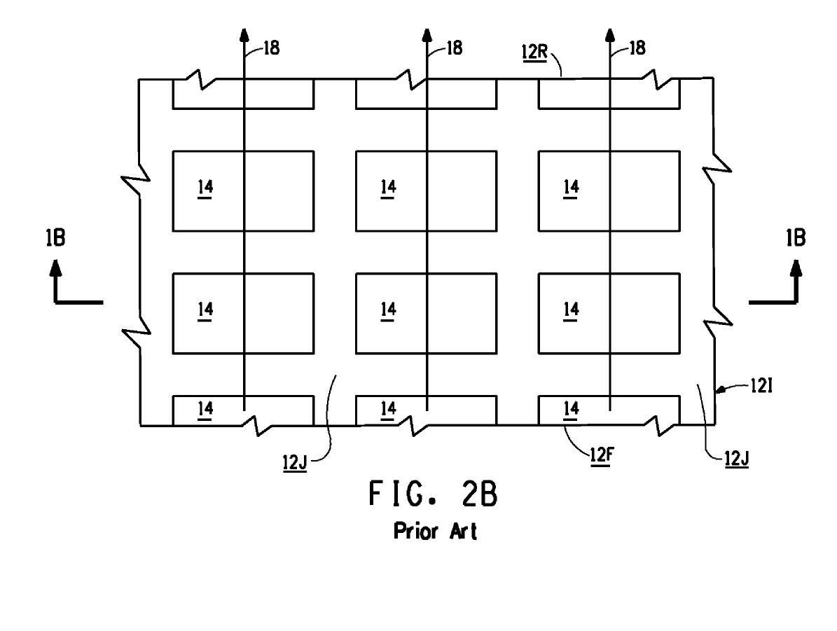

FIGS. 1A and 2A and FIGS. 1B and 2B illustrate highly stylized pictorial representations respectively illustrating side sectional and plan views of typical backplane structures available in the prior art upon which an organic electronic device may be fabricated using a process in accordance with the present invention. The backplane structures are generally indicated in this application by the reference character 12 while the organic electronic device (throughout its various stages of fabrication) is generally indicated in later Figures by the reference character 10. Regardless of the depictions shown in FIGS. 1A through 2B it should be understood that any suitable alternative backplane construction may be utilized. It should be emphasized that all of the drawings in this application are intended only for illustrative purposes, are not to scale, and are not intended to depict the actual relative dimensions among the various layers and elements of the backplane structures 12 or of the device 10.

As shown in FIGS. 1A and 1B, the backplane 12 includes a substrate 12S on which is built the array of transistors 12T and conductors 12C that form the drive network of addressing and control elements for the device 10. The substrate 12S may be transparent or opaque to the passage of light depending upon whether the device 10 exhibits a conventional or top emission structure. A suitable transparent substrate material is glass. An insulating layer 121 is disposed on the substrate and covers the elements of the addressing and control network. The surface of the insulating layer 121 is indicated at reference character 12J.

An electrode 14, typically an anode, for each display subpixel of the device 10 is provided on the surface 12J of the insulating layer 12I. Each anode 14 is connected to the drive network via a contact 14L that extends through the insulating layer 12I. As with the case of the substrate 12S, each anode 14 may be transparent or opaque to the passage of light, again dependent upon whether the device 10 exhibits a conventional or top emission structure.

The anode is the electrode that is particularly efficient for injecting positive charge carriers into the electronic device. It can be made, for example, from materials containing a metal, mixed metal, alloy, metal oxide or mixed-metal oxide, or it can be a conducting polymer, and mixtures thereof. Suitable metals include the Group 11 metals, the metals in Groups 4, 5, and 6, and the Group 8 10 transition metals. If the anode is to be light-transmitting, mixed-metal oxides of Groups 12, 13 and 14 metals are generally used. Examples of suitable materials include, but are not limited to, indium-tin-oxide (“ITO”). indium-zinc-oxide (“IZO”), aluminum-tin-oxide (“ATO”), aluminum-zinc-oxide (“AZO”), and zirconium-tin-oxide (“ZTO”).

As shown in FIGS. 2A and 2B, each electrode 14 for each subpixel in the device is a substantially rectangular member when viewed in plan. The electrodes 14A are arrayed in linear lanes 18 that longitudinally extend across the surface of the insulating layer 12I from the front edge surface 12F to the rear edge surface 12R thereof.

In a backplane structure as shown in FIG. 1B, the anode 14 is deposited directly on and sits slightly proud of the surface 12J of the insulating layer 12I. In the alternative structure shown in FIG. 1A, the backplane 12 is provided with one (or more) passivation, stabilization, and/or other material(s) that are disposed on and merge with the insulating layer 12I. These additional material(s) define boundary banks 12B that extend longitudinally from front to rear on the surface of the substrate between adjacent lanes 18 of anodes. The boundary banks 12B extend for a predetermined distance 12H (FIG. 1A) above the surface 12J of the insulating layer 12I and lie above the thickness dimension of the anodes 14. Such longitudinal bank structures 12B are intended to serve as physical containment to isolate adjacent pixel lanes 18. Further isolation of individual anodes 14 along a given lane 18 may be achieved by including transverse structures 12B′ (FIG. 2A) as part of the banks network. Boundary bank structures that include both elongated and transverse banks 12B, 12B′, respectively, serve to create individualized wells surrounding each anode. The material forming the longitudinal portion 12B (and transverse portions 12B′ (if provided) of the banks may be arranged so as to overlap the margin of each of the anodes 14 (as suggested at reference character 12M, FIG. 1A) while the major portion of the surface of each anode 14 is left exposed.

As will be discussed, the insulating material 12I and the material(s) forming the boundary bank structures 12B, 12B′ each exhibit predetermined energy absorbance characteristics. Generally speaking, the insulating material 12I and the bank structures 12B, 12B′ may be fabricated from either organic resist materials (such as polyimide, polyacrylate, or phenolic/DCNQ resists) or inorganic materials (such as silicon oxide or silicon nitride). In some embodiments the insulating material 12I is inorganic while the bank structures 12B, 12B′ are organic.

In some embodiments, the insulating and passivation materials include an additive material that increases the response of the insulating and passivation materials when exposed to incident energy and enhances the conversion of the incident energy into heat. The purpose is to confine heating effects near the surface of the insulating and passivation materials so as to avoid damage to underlying circuitry. This is especially important for high resolution displays that require narrow containment geometries. These additive materials include pigments or dyes that, when added to the boundary bank material, increase the optical density at the wavelength of an energy source (be it laser or otherwise). The presence of the additive material increases the optical density of the boundary bank material relative to the optical density of the boundary bank material without the presence of the additive. If the boundary bank material is a photoresist, the additive loading and absorption spectrum of the additive material can be chosen so as to maintain adequate transmission for photopatterning. Examples of the additive material include, but are not limited to, triarylmethane compounds, azo compounds, xanthenes, acridiniums, phenazines, thiazenes, or phthalocyanine dyes, carbon black, or metal oxide pigments.

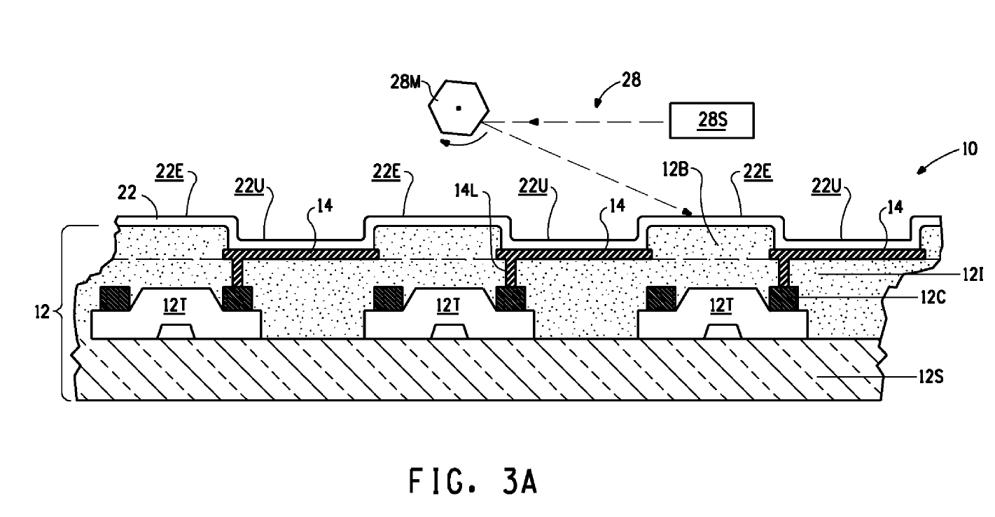

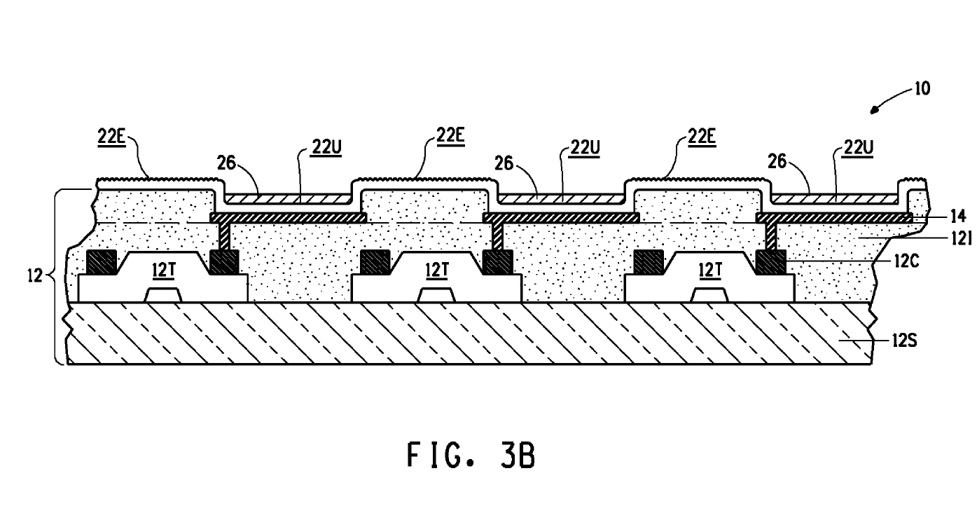

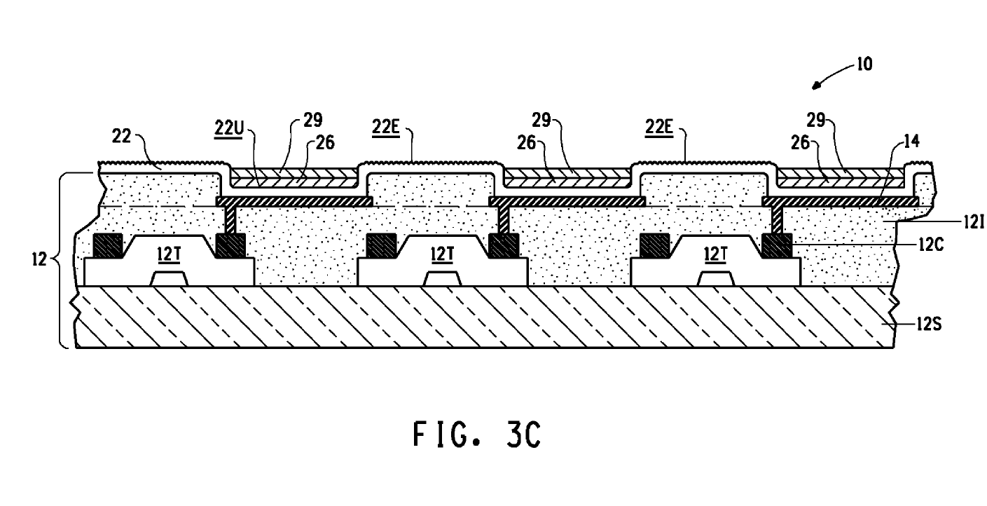

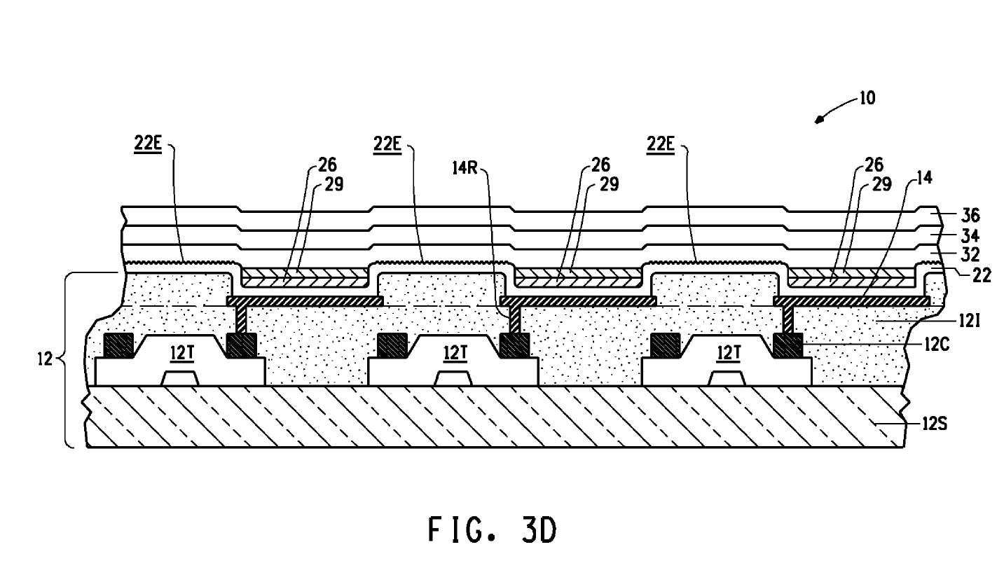

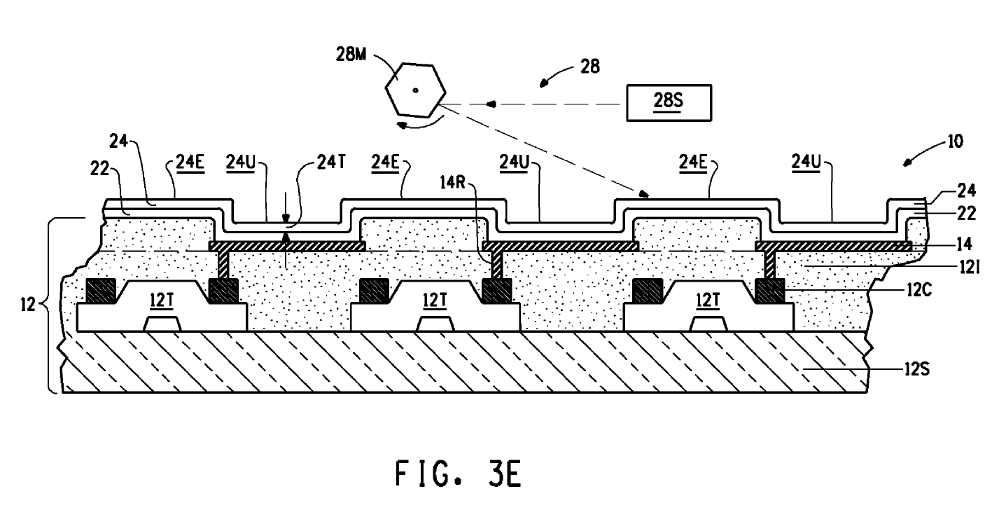

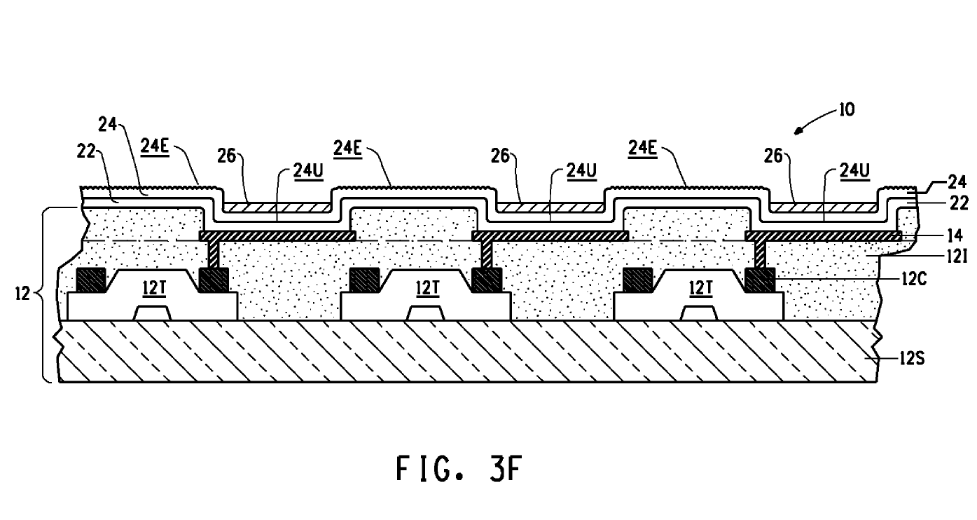

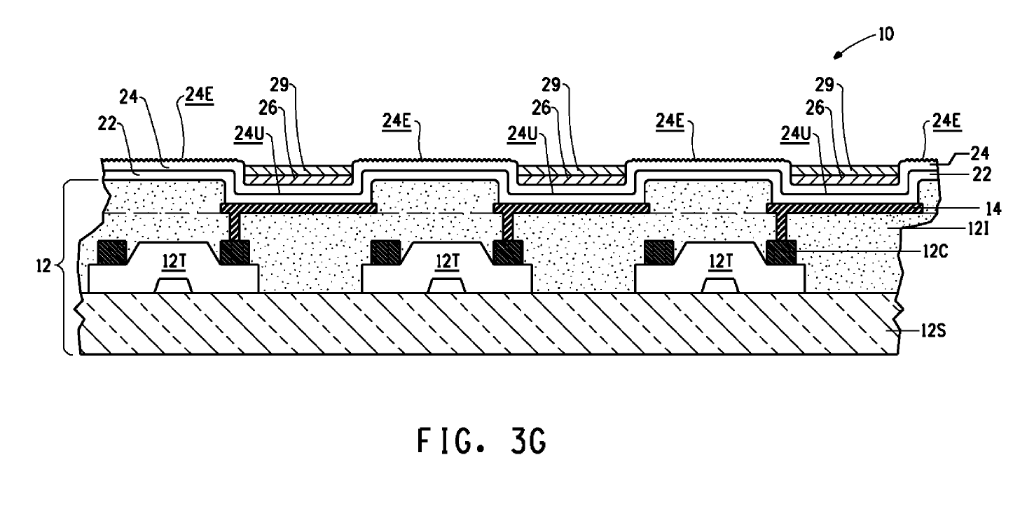

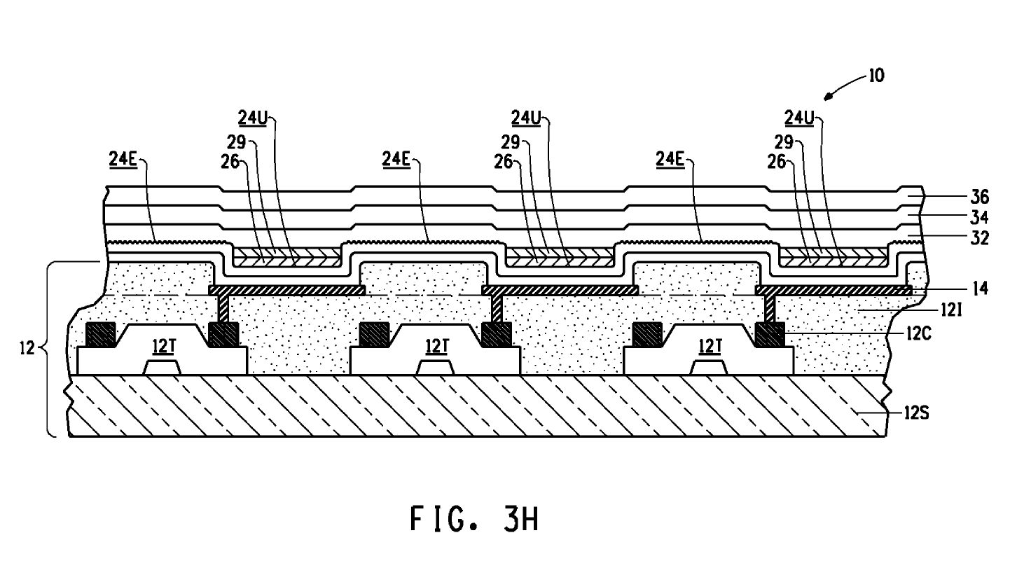

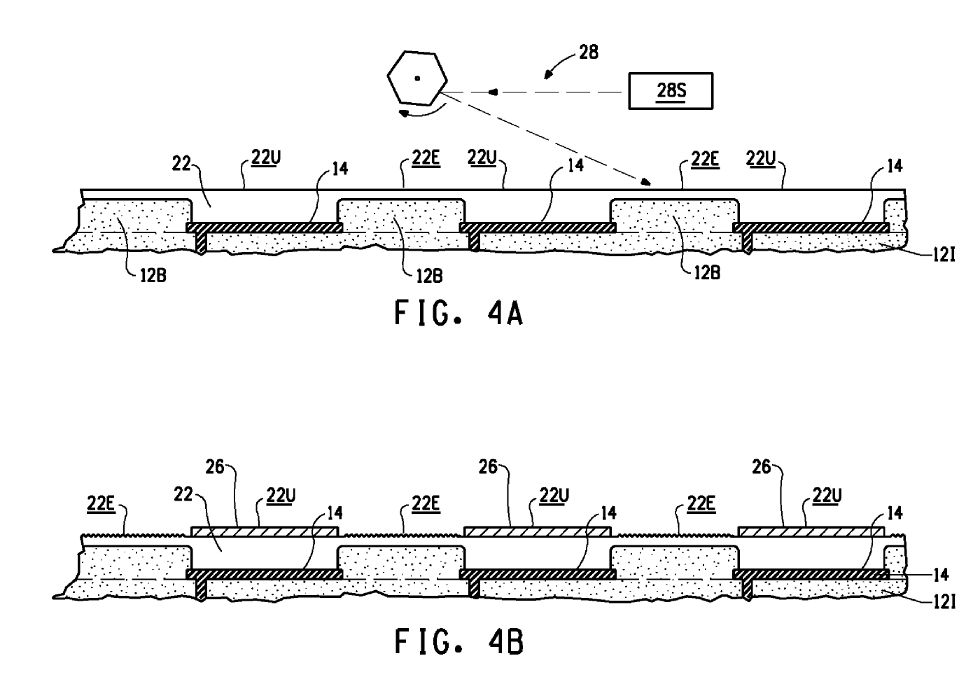

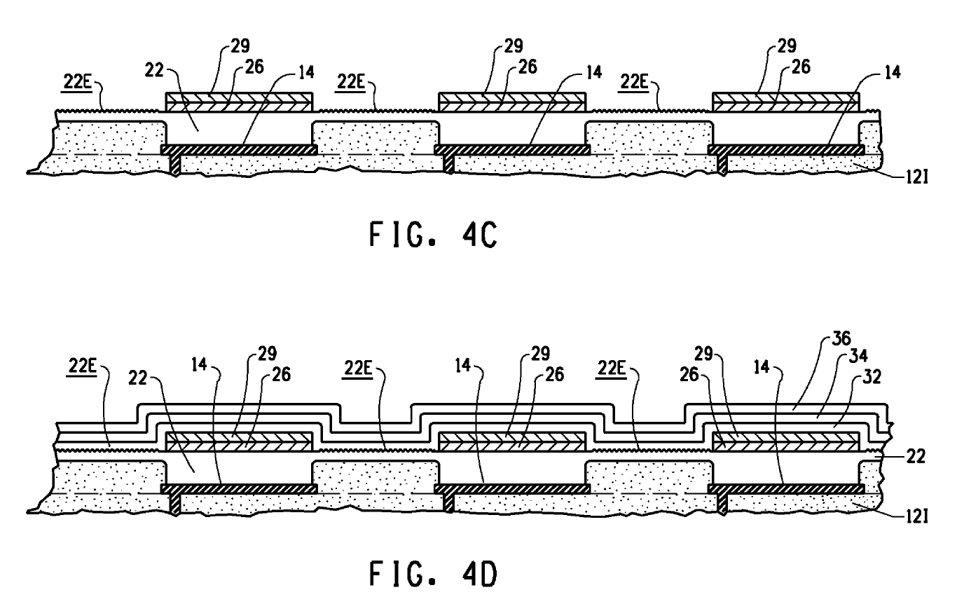

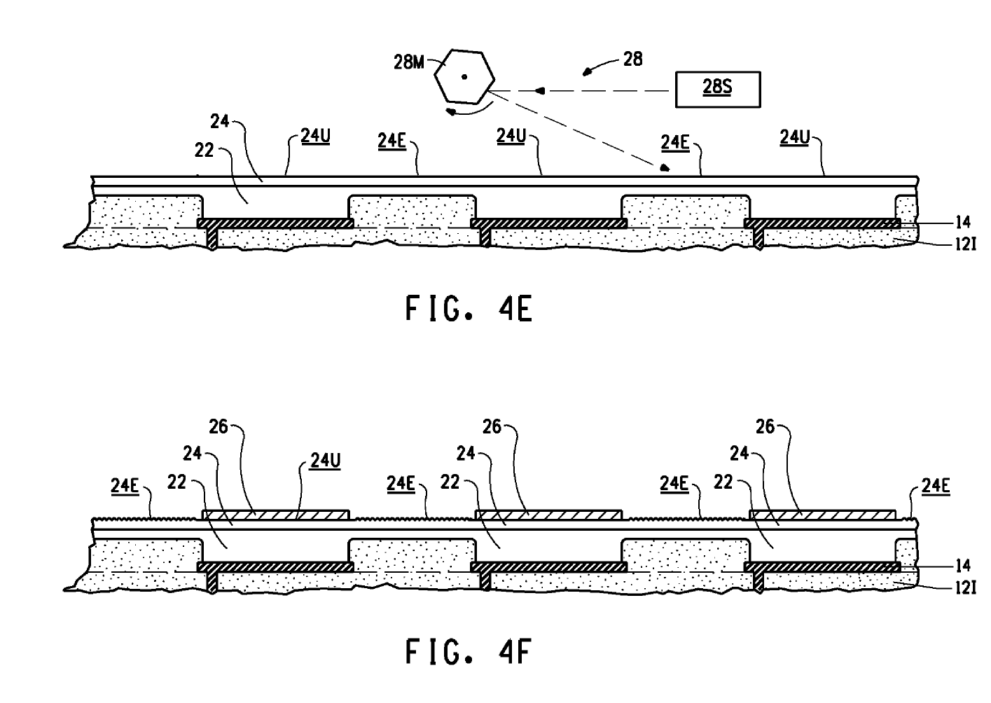

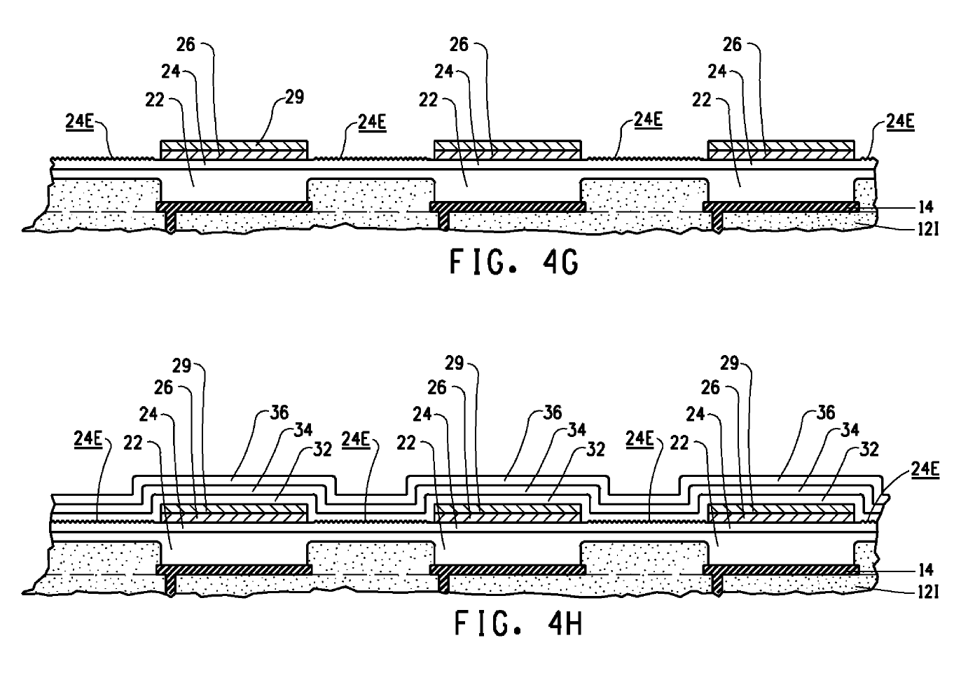

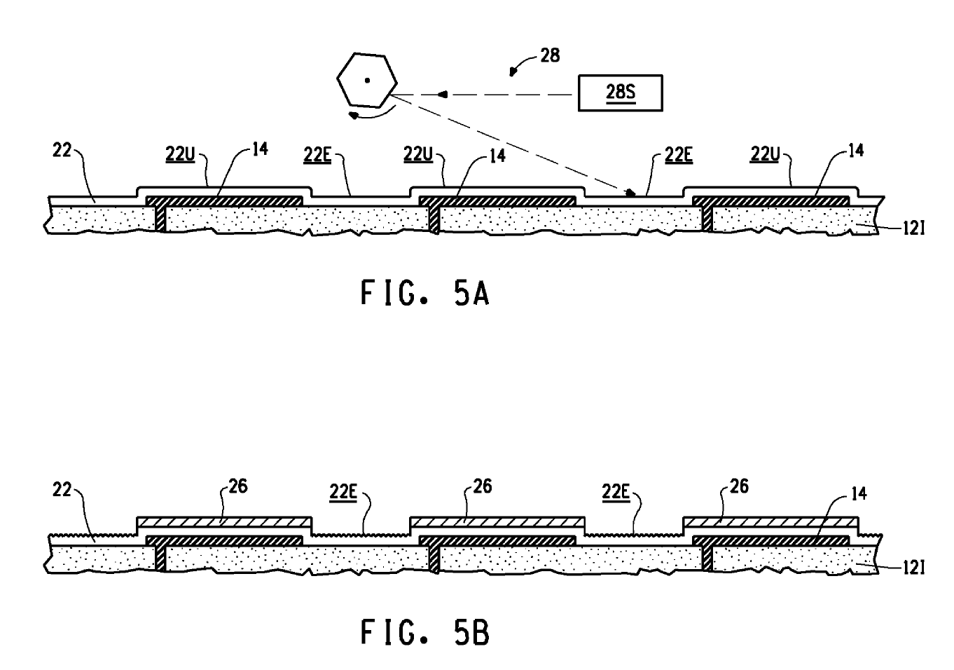

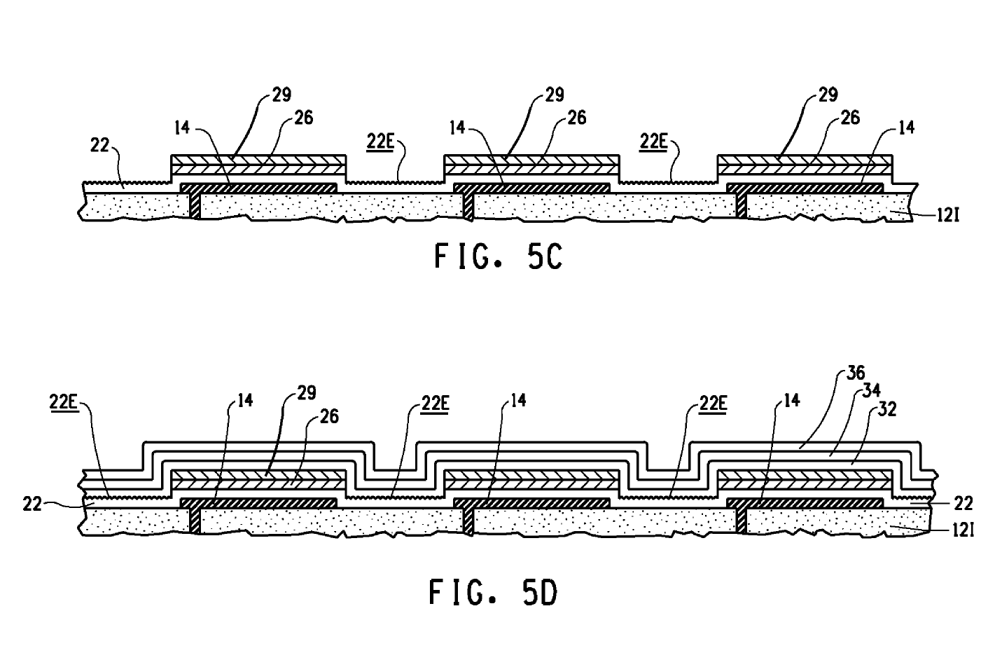

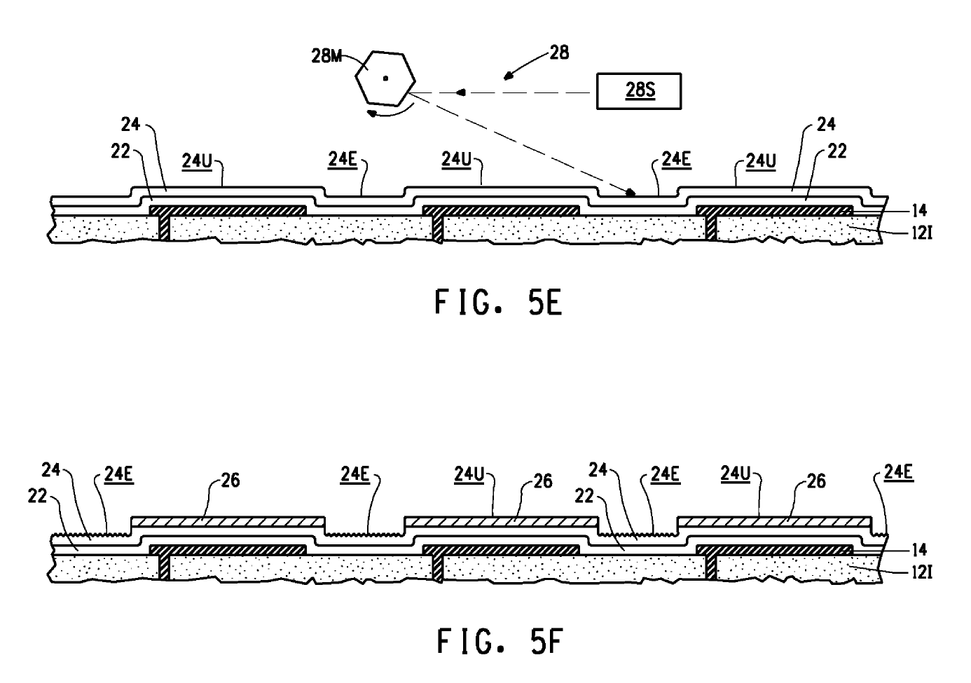

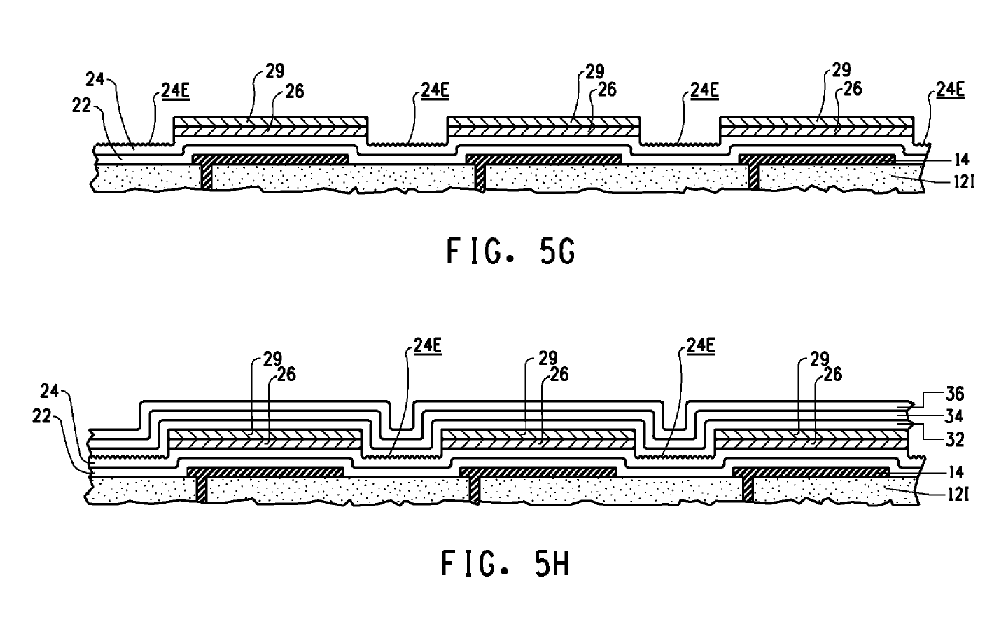

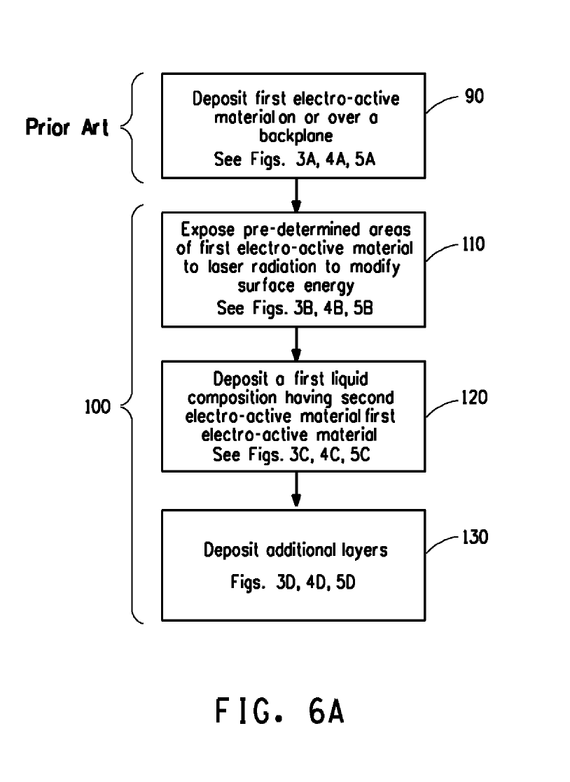

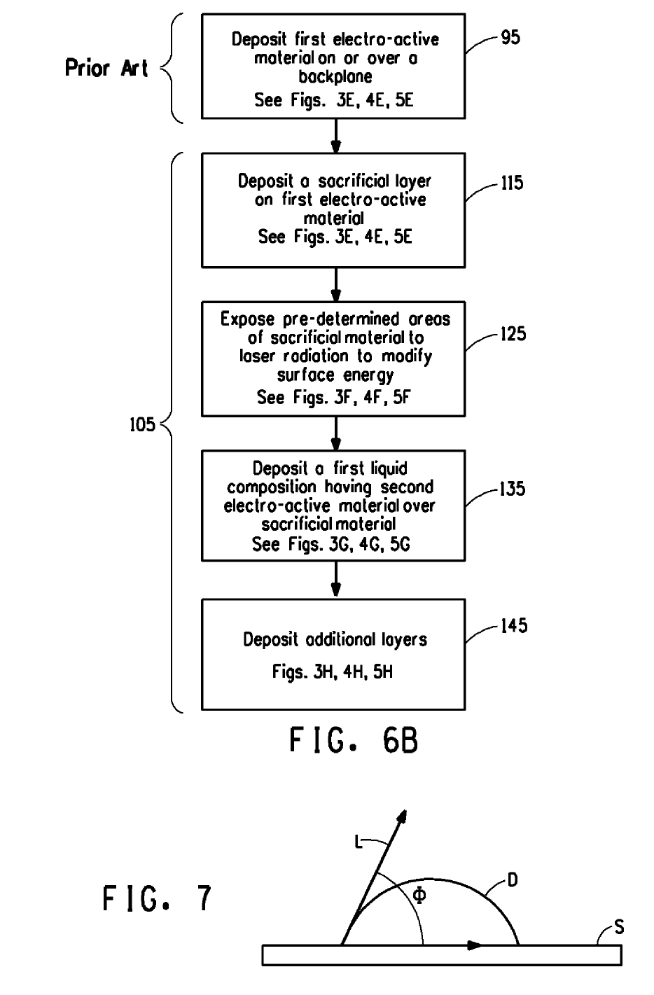

Process steps involved in the manufacture an electronic device 10 using a process in accordance with some embodiments of the present invention are graphically illustrated in FIGS. 3A through 3H and FIGS. 4A through 4H (for a backplane 12 of the form shown in FIGS. 1A, 2A) and in FIGS. 5A through 5H (for a backplane 12 of the form shown in FIGS. 1B, 2B). An overall block diagram of the steps of the process 100 of some embodiments of the present invention is set forth in FIGS. 6A and 6B.

As an initial step practiced in the art when forming a device 10, a layer 22 of a first organic electro-active material is deposited on the exterior surface of the backplane 12 (including the surface of the anodes 14). This step is denoted in block 90 in FIG. 6A. The layer 22 may be substantially uniform in thickness (e.g., FIGS. 3A, 5A) in which case the presence of the boundary banks and the individualized wells are still discernible. Alternatively, the layer 22 may be deposited such that it presents a substantially planar surface across the breadth of the backplane (e.g., FIG. 4A), thereby obscuring the presence of the boundary banks and the individualized wells. The hole injection layer 22 may have a thickness in the range from about twenty to about three hundred nanometers (20-300 nm) and, for example, in the range from about forty to about fifty nanometers (40-50 nm) and between two hundred and two hundred sixty nanometers (200-260 nm).

As used in this specification (including the claims) the term “on” when used in connection with the placement of materials denoted the placement of a second material directly onto (i.e., into physical adjacency with) the surface of a first material. There is no intermediate material present between the first and second materials. Thus, in the case of the hole injection material 22, the term “on” denotes that the hole injection material (a “second” material”) is placed directly onto the surface of the topmost layer (a “first material”) of the backplane 12.

As used in this specification (including the claims) the term “over” is meant to encompass both: (1) the disposition of a second material “on” a first material; and, (2) the disposition of the second material on a material or surface that is itself intermediate between the first material and the second material.

The term “hole injection material” or “hole injection composition” or like terms is intended to mean an electrically conductive or semi-conductive layer or material which may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device.

Hole injection materials may be polymers, oligomers, or small molecules, and may be applied in the form of solutions, dispersions, suspensions, emulsions, colloidal mixtures, or other compositions. The full details of the hole injection composition are set forth hereinafter. In some embodiments, the hole injection composition includes an electrically conductive polymer and a highly-fluorinated acid polymer that has a first predetermined surface energy associated therewith. This hole injection composition contains certain chemical species which are believed to impart a beneficial chemical containment property, as will be developed.

As discussed in the Background it is necessary to provide some form of containment to inhibit the natural tendency of a liquid composition to spread beyond the area where it is deposited. The physical containment barriers (i.e., the bank structures 12B, 12B′) exhibited by the backplane as shown in FIGS. 1A and 2A may not be sufficient to provide the necessary containment. In accordance with some embodiments of the present invention, chemical containment in the form of surface energy changes are produced that serve to chemically contain the liquid composition and prevent its migration.

One step for manufacturing an electronic device in accordance with the process 100 of some embodiments of the present invention is indicated in block 110 of the process diagram of FIG. 6A (referencing FIGS. 3A, 4A and 5A). In this step predetermined areas 22E of the hole injection material 22 are exposed to radiation, such as from a laser. Unexposed areas are indicated by the reference character 22U. The exposed areas 22E are positioned intermediate the anodes 14 and, for example, in general alignment with the boundary banks 12B (if provided) in the backplane.

The radiation, such as from a laser, has a predetermined wavelength and energy density that are chosen in accordance with absorbance characteristics of the hole injection material and the material of the backplane. The laser wavelength can be in the range from ultraviolet through visible and into the infrared portions of the spectrum. The energy content of the laser radiation is in the range from about one milliJoule per square centimeter to about ten Joules per square centimeter. The energy content of the radiation is selected such that energy is absorbed within the organic hole injection material and in the regions of the backplane in the path of the laser radiation to an extent sufficient to prevent the occurrence of deleterious heating effects to the elements of a drive and control network.

A laser system, diagrammatically indicated in FIGS. 3A, 4A, 5A at reference character 28, includes a laser source 28S and a suitable beam director, such as a movable mirror 28M. Of course, any suitable scheme (including a movable stage) may be employed to cause relative motion of the laser radiation with respect to the surface of the hole injection material. The areas 22E exposed to the laser radiation are shown by undulating lines in FIGS. 3B, 4B, 5B for clarity of illustration.

The wavelength and energy density (energy per unit area) of the laser system 28 are chosen in accordance with the absorbance characteristics of the materials forming the regions of the backplane beneath the exposed regions 22E. Generally speaking, the operating parameters of the laser system are selected such that a sufficient portion of the incident energy content is attenuated by the layer 22 and the backplane to prevent heat caused by laser exposure from deleteriously affecting the elements of the drive and control network.

The laser wavelength can be in the range from ultraviolet through visible and into the infrared portions of the spectrum (i.e., from about 150 nanometers through about ten micrometers). Other parameters of laser operation (e.g., intensity, pulse rate, beam size, traversing speed) are selected such that an energy density in the range from about one milliJoule per square centimeter to about ten Joules per square centimeter is delivered to the exposed areas 22E.

The incident energy from the laser heats the hole injection material 22 to an extent sufficient to cause the exposed areas 22E to have a second, lower, surface energy associated therewith. For example, the laser treatment imparts a second, lower, surface energy to the treated areas that renders the treated areas non-wettable by a material having a higher surface energy. It is believed that the surface energy reversal of the treated areas may be due to the migration of fluorinated sulfonic acid polymers toward the surface of the hole injection layer 22.

The relative surface energies of the exposed areas 22E with respect to the unexposed areas 22U may be determined by a comparison of the contact angle of a given test liquid on the surface of the different areas. FIG. 7 is a definitional diagram from which an understanding of the manner by which the contact angle may be derived.

As shown in FIG. 7, for a droplet D of a test liquid disposed on a surface S the contact angle Φ is defined by the intersection of the plane of the surface S and a line L from the outer edge of the droplet D to the surface S. The angle Φ is measured after the droplet has reached an equilibrium position on the surface after being applied, i.e. “static contact angle.” A variety of manufacturers make equipment capable of measuring contact angles. One such device for measuring contact angle is a device known as a goniometer.

As noted earlier contact angle is a measure of surface energy and, hence, the wettability of the surface S by a liquid. Contact angle increases as surface energy of the surface decreases. A high contact angle indicates a low surface energy, and a relatively low surface energy prevents a liquid from wetting onto that surface.

Conversely, if the surface energy of the surface S is higher than the surface energy of a liquid dispensed thereon, the liquid wets, or spreads onto, the surface. A relatively high surface energy facilitates the wetting of a liquid onto that surface. In this case the value of the contact angle will be low, e.g., near zero degrees) (0°).

In order to obtain meaningful contact angle information it is advantageous to choose a test liquid that does not have a very high or very low surface tension or surface energy. Liquids with very high surface tension will not wet either the non-treated or laser-treated areas. Liquids with very low surface tension will wet both.

For example, the test liquid is an aromatic liquid, such as an aromatic ester or aromatic ether. A suitable test liquid is a benzene derivative having one or more substituents selected from the group consisting of alkyl groups, alkoxy groups, ethers, esters, and combinations thereof.

In some embodiments of the present invention, the non-treated (unexposed) area 22U of the hole injection layer has a contact angle with anisole of less than seventy degrees (70°); for example, less than seventy degrees (60°); and for example, less than fifty degrees) (50°).

It is informative to measure the difference in surface energy between laser-treated (“LT”) and non-treated (“NT”) areas. Using anisole as a test liquid, the difference in contact angle between the unexposed, non-treated areas 22U and the exposed, laser-treated areas 22E [hereinafter referred to as ΔCT_{(LT-NT)}] in some embodiments is at least twenty degrees (20°), which means that the contact angle with anisole for the unexposed areas 22U is at least twenty degrees (20°) less than the contact angle for the exposed, laser-treated areas 22E. In some embodiments, ΔCT_{(LT-NT)} is at least twenty-five degrees (25°); for example, ΔCT_{(LT-NT)} is at least thirty degrees (30°); and, for example, ΔCT_{(LT-NT)} is at least forty degrees (40°).

After the laser treatment, a liquid composition including a second electro-active material 26, such as an organic hole transport material, is deposited directly on the layer 22 of the hole injection material, as illustrated at element 120 of the method 100. Details of the hole transport composition are set forth herein.

The liquid composition containing the hole transport material may be deposited using any conventional liquid deposition method. For liquid deposition methods, a suitable solvent for a particular compound or related class of compounds readily can be determined by one skilled in the art. Suitable classes of solvents include, but are not limited to, aliphatic hydrocarbons (such as decane and hexadecane), halogenated hydrocarbons (such as methylene chloride, chloroform, chlorobenzene, and perfluoroheptane), aromatic hydrocarbons (such as non-substituted and alkyl- and alkoxy-substituted toluenes and xylenes), aromatic ethers (such as anisole and dibenzyl ether), heteroaromatics (such as pyridine) polar solvents (such as tetrahydropyran (“THP”), dimethylacetamide (“DMAC”) and N-methylpyrrolidone (“NMP”)), esters (such as ethylacetate, propylene carbonate, and methyl benzoate), alcohols and glycols (such as isopropanol and ethylene glycol), glycol ethers and derivatives (such as propylene glycol methyl ether and propylene glycol methyl ether acetate), and ketones (such as cyclopentanone and diisobutyl ketone).

As shown in FIGS. 3B, 4B and 5B, due to the difference in surface energy between the liquid hole transport composition and the laser-treated areas 22E, the liquid hole transport composition wets only those areas 22U having the higher surface energy to the substantial exclusion of the exposed areas 22E having the lower surface energy, thus containing the liquid hole transport composition.

In some embodiments, additional layers of material are deposited on the structure produced in FIGS. 3B, 4B and 5B, as illustrated in block 130 of FIG. 6A. As shown in FIGS. 3C, 4C and 5C, a second liquid composition that includes an organic electro-active emissive material 29 is deposited on the hole transport for some embodiments. The same liquid deposition techniques may be used for this deposition. The difference in surface energy which serves to contain the layer 26 operates in the same way to contain the electro-active emissive material 29.

As illustrated at block 130 in FIG. 6A, in some embodiments further layers of materials, such as an electron transport layer 32, an electron ejection layer 34, and a cathode 36, are sequentially deposited on previously deposited layers (FIGS. 3D, 4D and 5D) to complete the device 10. Since these layers 32, 34 and 36 are typically deposited using a vapor deposition or a thermal transfer technique, the difference in surface energies between exposed and unexposed areas does not limit the areas of deposition. Conventional vapor deposition techniques can be used, such as thermal evaporation, chemical vapor deposition, sputtering, and the like. The organic layers can be applied from solutions or dispersions in suitable solvents, using conventional coating or printing techniques, including but not limited to, spin-coating, dip-coating, roll-to-roll techniques, ink-jet printing, continuous nozzle printing, screen-printing, gravure printing, and the like.

In some embodiments, the efficiency of devices made as described herein is further improved by optimizing the other layers in the device. For example, more efficient cathodes such as Ca, Ba or LiF can be used. Shaped substrates and novel hole transport materials that result in a reduction in operating voltage or increase quantum efficiency are also applicable. Additional layers can also be added to tailor the energy levels of the various layers and facilitate electroluminescence.

One step for manufacturing an electronic device in accordance with the process 105 of some embodiments of the present invention is indicated in block 95 of the process diagram of FIG. 6B (referencing FIGS. 3E, 4E and 5E). In this step, a layer 24 of a sacrificial material is deposited on the hole injection layer 22. The sacrificial material 24 is non-reactive and electrically compatible with the hole injection material. By “electrically compatible” it is meant that the sacrificial material 24 does not interfere with hole injection and hole transport functions of the hole injection and hole transmission materials.

A suitable sacrificial material useful with the preferred hole injection composition can be any oxide of Group 3-13 metals, any electrically insulative oxide set forth herein, or any semiconductive metal oxide set forth herein. A preferred material for the sacrificial layer is molybdenum oxide (MoOₓ, such as MoO₂ or MoO₃). Molybdenum nitrides also can be used.

In some embodiments, the thickness dimension 24T of the sacrificial material 24 is relatively thin when compared to the thickness dimension of the hole injection material 22 on which it is deposited. For example, the thickness of the sacrificial material is on the order of one to five nanometers (1-5 nm).

As discussed in the Background it is necessary to provide some form of containment to inhibit the natural tendency of a liquid composition to spread beyond the area where it is deposited. The physical containment barriers (i.e., the bank structures 12B, 12B′) exhibited by the backplane as shown in FIGS. 1A and 2A may not be sufficient to provide the necessary containment. In accordance with some embodiments of the present invention, chemical containment in the form of surface energy changes are produced that serve to chemically contain the liquid composition and prevent its migration.

As indicated in block 115 of the process diagram of FIG. 6A, once the layer 24 is in place, predetermined areas 24E of the sacrificial material are exposed to radiation, such as from a laser, for some embodiments. Unexposed areas are indicated by the reference character 24U. The exposed areas 24E are positioned intermediate the anodes and, for example, in general alignment with the boundary banks 12B (if provided) in the backplane.

The radiation, such as from a laser, has a predetermined wavelength and energy density that are chosen in accordance with absorbance characteristics of the sacrificial material, the hole injection material, and the material of the backplane. The laser wavelength can be in the range from ultraviolet through visible and into the infrared portions of the spectrum. The energy content of the laser radiation is in the range from about one milliJoule per square centimeter to about ten Joules per square centimeter. The energy content of the radiation is selected such that energy is absorbed within the organic hole injection material and in the regions of the backplane in the path of the laser radiation to an extent sufficient to prevent the occurrence of deleterious heating effects to the elements of a drive and control network.

A laser system, diagrammatically indicated in FIG. 3E at reference character 28, includes a laser source 28S and a suitable beam director, such as a movable mirror 28M. Of course, any suitable scheme (including a movable stage) may be employed to cause relative motion of the laser radiation with respect to the surface of the hole injection material. The areas 24E exposed to the laser radiation are shown in FIGS. 3F, 4F, and 5F by undulating lines for clarity of illustration.

The wavelength and energy density (energy per unit area) of the laser system 28 are chosen in accordance with the absorbance characteristics of the materials forming the regions of the backplane beneath the exposed regions 24E. Generally speaking, the operating parameters of the laser system are selected such that a sufficient portion of the incident energy content is attenuated by the layers 22, 24 and the backplane to prevent heat caused by laser exposure from deleteriously affecting the elements of the drive and control network.

The laser wavelength can be in the range from ultraviolet, through visible and into the infrared portions of the spectrum (i.e., from about 150 nanometers through about ten micrometers). Other parameters of laser operation (e.g., intensity, pulse rate, beam size, traversing speed) are selected such that an energy density in the range from about one milliJoule per square centimeter to about ten Joules per square centimeter is delivered to the exposed areas 24E.

The incident energy from the laser heats the sacrificial material 24 to an extent sufficient to cause the exposed areas 24E to have a second, lower, surface energy associated therewith. In some embodiments, the laser treatment imparts a second, lower, surface energy to the treated areas that renders the treated areas non-wettable by a material having a higher surface energy. It is believed that the surface energy reversal of the treated areas may be due to the migration of fluorinated sulfonic acid polymers from the preferred hole injection layer 22 toward the surface of the sacrificial material 24.

The relative surface energies of the exposed areas 24E with respect to the unexposed areas 24U may be determined by a comparison of the contact angle of a given test liquid on the surface of the different areas. FIG. 7 is a definitional diagram from which an understanding of the manner by which the contact angle may be derived.

As shown in FIG. 7, for a droplet D of a test liquid disposed on a surface S the contact angle Φ is defined by the intersection of the plane of the surface S and a line L from the outer edge of the droplet D to the surface S. The angle Φ is measured after the droplet has reached an equilibrium position on the surface after being applied, i.e. “static contact angle.” A variety of manufacturers make equipment capable of measuring contact angles. One such device for measuring contact angle is a device known as a goniometer.

As noted earlier contact angle is a measure of surface energy and, hence, the wettability of the surface S by a liquid. Contact angle increases as surface energy of the surface decreases. A high contact angle indicates a low surface energy, and a relatively low surface energy prevents a liquid from wetting onto that surface.

Conversely, if the surface energy of the surface S is higher than the surface energy of a liquid dispensed thereon, the liquid wets, or spreads onto, the surface. A relatively high surface energy facilitates the wetting of a liquid onto that surface. In this case the value of the contact angle will be low, e.g., near zero degrees) (0°).

In order to obtain meaningful contact angle information it is advantageous to choose a test liquid that does not have a very high or very low surface tension or surface energy. Liquids with very high surface tension will not wet either the non-treated or laser-treated areas. Liquids with very low surface tension will wet both.

In some embodiments, the test liquid is an aromatic liquid, such as an aromatic ester or aromatic ether. A suitable test liquid is a benzene derivative having one or more substituents selected from the group consisting of alkyl groups, alkoxy groups, ethers, esters, and combinations thereof.

In some embodiments of the present invention, the non-treated (unexposed) area 24U of the hole injection layer is quite wettable. In some embodiments, area 24U has a contact angle with anisole close to zero, or at least less than twenty degrees (20°) degrees. In some embodiments, the exposed area has a contact angle with anisole greater than forty degrees)(40°).

It is informative to measure the difference in surface energy between laser-treated (“LT”) and non-treated (“NT”) areas. Using anisole as a test liquid, the difference in contact angle between the unexposed, non-treated areas 24U and the exposed, laser-treated areas 24E [hereinafter referred to as ΔCT_{(LT-NT)}] is at least twenty degrees (20°) in some embodiments, which means that the contact angle with anisole for the unexposed areas 24U is at least twenty degrees (20°) less than the contact angle for the exposed, laser-treated areas 24E. in some embodiments, ΔCT_{(LT-NT)} is at least twenty-five degrees (25°); for example, ΔCT_{(LT-NT)} is at least thirty degrees (30°); and, for example, ΔCT_{(LT-NT)} is at least forty degrees)(40°).

After the laser treatment, a liquid composition including a second electro-active material 26, such as an organic hole transport material, is deposited directly on the layer 24 of the sacrificial material, as illustrated at element 125 of the method 105 (FIGS. 3F, 4F, 5F). Details of the hole transport composition are set forth herein.

The liquid composition containing the hole transport material may be deposited using any conventional liquid deposition method. For liquid deposition methods, a suitable solvent for a particular compound or related class of compounds can be readily determined by one skilled in the art. Suitable classes of solvents include, but are not limited to, aliphatic hydrocarbons (such as decane and hexadecane), halogenated hydrocarbons (such as methylene chloride, chloroform, chlorobenzene, and perfluoroheptane), aromatic hydrocarbons (such as non-substituted and alkyl- and alkoxy-substituted toluenes and xylenes), aromatic ethers (such as anisole and dibenzyl ether), heteroaromatics (such as pyridine) polar solvents (such as tetrahydropyran (“THP”), dimethylacetamide (“DMAC”) and N-methylpyrrolidone (“NMP”)), esters (such as ethylacetate, propylene carbonate, and methyl benzoate), alcohols and glycols (such as isopropanol and ethylene glycol), glycol ethers and derivatives (such as propylene glycol methyl ether and propylene glycol methyl ether acetate), and ketones (such as cyclopentanone and diisobutyl ketone).

As shown in FIGS. 3F, 4F and 5F, due to the difference in surface energy between the liquid hole transport composition and the laser-treated areas 24E of the sacrificial material, the liquid hole transport composition wets only those areas 24U having the higher surface energy to the substantial exclusion of the exposed areas 24E having the lower surface energy, thereby containing the liquid hole transport composition.

As illustrated in block 135 of FIG. 6B, additional layers of material are deposited on the structure produced (in FIGS. 3F, 4F and 5F) for some embodiments. As shown in FIGS. 3G, 4G and 5G, in some embodiments a second liquid composition that includes an organic electro-active emissive material 29 is deposited on the hole transport. The same liquid deposition techniques may be used for this deposition. The difference in surface energy which serves to contain the layer 26 operates in the same way to contain the electro-active emissive material 29.

Further layers of materials, such as an electron transport layer 32, an electron ejection layer 34, and a cathode 36, are sequentially deposited on previously deposited layers (FIGS. 3H, 4H and 5H) to complete the device 10 in some embodiments, as shown in element 145 of FIG. 6B. Since these layers 32, 34 and 36 are typically deposited using a vapor deposition or a thermal transfer technique, the difference in surface energies between exposed and unexposed areas does not limit the areas of deposition. Conventional vapor deposition techniques can be used, such as thermal evaporation, chemical vapor deposition, sputtering, and the like. The organic layers can be applied from solutions or dispersions in suitable solvents, using conventional coating or printing techniques, including but not limited to spin-coating, dip-coating, roll-to-roll techniques, ink-jet printing, continuous nozzle printing, screen-printing, gravure printing and the like.

The efficiency of devices made as described herein is further improved by optimizing the other layers in the device in some embodiments. For example, more efficient cathodes such as Ca, Ba or LiF can be used. Shaped substrates and novel hole transport materials that result in a reduction in operating voltage or increase quantum efficiency are also applicable. In some embodiments, additional layers are added to tailor the energy levels of the various layers and facilitate electroluminescence.

### Compositions

### A. Hole Injection Composition

The hole injection composition includes an electrically conductive polymer and a highly-fluorinated acid polymer.

In some embodiments, the hole injection composition includes (a) an electrically conductive polymer doped with a highly-fluorinated acid polymer.

In some embodiments, the hole injection composition includes (b) an electrically conductive polymer doped with a non-fluorinated polymeric acid in admixture with (c) a highly-fluorinated acid polymer.

In some embodiments, the hole injection composition includes (a) an electrically conductive polymer doped with a highly-fluorinated acid polymer and (d) nanoparticles.

In some embodiments, the hole injection composition includes (b) an electrically conductive polymer doped with a non-fluorinated polymeric acid, (c) a highly-fluorinated acid polymer, and (d) nanoparticles.

In some embodiments, the hole injection composition includes optional additives.

In some embodiments, the hole injection composition consists essentially of an electrically conductive polymer and a highly-fluorinated acid polymer.

In some embodiments, the hole injection composition consists essentially of (a) an electrically conductive polymer doped with a highly-fluorinated acid polymer.

In some embodiments, the hole injection composition consists essentially of (b) an electrically conductive polymer doped with a non-fluorinated polymeric acid in admixture with (c) a highly-fluorinated acid polymer.

In some embodiments, the hole injection composition consists essentially of (a) an electrically conductive polymer doped with a highly-fluorinated acid polymer and (d) nanoparticles.

In some embodiments, the hole injection composition consists essentially of (b) an electrically conductive polymer doped with a non-fluorinated polymeric acid, (c) a highly-fluorinated acid polymer, and (d) nanoparticles.

### 1. Electrically Conductive Polymer

The electrically conductive polymers suitable for the hole injection materials are made from at least one monomer which, when polymerized alone, forms an electrically conductive homopolymer. Such monomers are referred to herein as “conductive precursor monomers.”Monomers which, when polymerized alone form homopolymers which are not electrically conductive, are referred to as “non-conductive precursor monomers.” The electrically conductive polymer can be a homopolymer or a copolymer. Electrically conductive copolymers suitable for the hole injection layer are made from two or more conductive precursor monomers or from a combination of one or more conductive precursor monomers and one or more non-conductive precursor monomers.

In some embodiments, the electrically conductive polymer is deuterated. In some embodiments, the deuterated electrically conductive polymer can be made from deuterated conductive precursor monomers. In some embodiments, the deuterated electrically conductive polymer can be made from non-deuterated conductive precursor monomers and then deuterated after polymerization.

In some embodiments, the electrically conductive polymer is made from at least one precursor monomer selected from thiophenes, selenophenes, tellurophenes, pyrroles, anilines, 4-amino-indoles, 7-amino-indoles, polycyclic aromatics, and deuterated analogs thereof. The polymers made from these monomers are referred to herein as polythiophenes, poly(selenophenes), poly(tellurophenes), polypyrroles, polyanilines, poly(4-amino-indoles), poly(7-amino-indoles), and polycyclic aromatic polymers, respectively. The term “polycyclic aromatic” refers to compounds having more than one aromatic ring. The rings may be joined by one or more bonds, or they may be fused together. The term “aromatic ring” is intended to include heteroaromatic rings. A “polycyclic heteroaromatic” compound has at least one heteroaromatic ring. In some embodiments, the polycyclic aromatic polymers are poly(thienothiophenes).

In some embodiments, monomers contemplated for use to form the electrically conductive polymer include Formula I below:

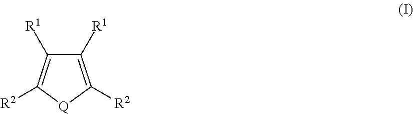

wherein:
Q is selected from the group consisting of S, Se, and Te;
R¹ is independently selected so as to be the same or different at each occurrence and is selected from hydrogen, deuterium, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphoric acid, halogen, nitro, cyano, hydroxyl, epoxy, silane, siloxane, alcohol, benzyl, carboxylate, ether, ether carboxylate, amidosulfonate, ether sulfonate, ester sulfonate, and urethane; or both R¹ groups together may form an alkylene or alkenylene chain completing a 3, 4, 5, 6, or 7-membered aromatic or alicyclic ring, which ring may optionally include one or more divalent nitrogen, selenium, tellurium, sulfur or oxygen atoms; and
R² is H or D.

As used herein, the term “alkyl” refers to a group derived from an aliphatic hydrocarbon and includes linear, branched and cyclic groups which may be unsubstituted or substituted. The term “heteroalkyl” is intended to mean an alkyl group in which one or more of the carbon atoms within the alkyl group has been replaced by another atom, such as nitrogen, oxygen, sulfur, and the like. The term “alkylene” refers to an alkyl group having two points of attachment.

As used herein, the term “alkenyl” refers to a group derived from an aliphatic hydrocarbon having at least one carbon-carbon double bond, and includes linear, branched and cyclic groups which may be unsubstituted or substituted. The term “heteroalkenyl” is intended to mean an alkenyl group, wherein one or more of the carbon atoms within the alkenyl group has been replaced by another atom, such as nitrogen, oxygen, sulfur, and the like. The term “alkenylene” refers to an alkenyl group having two points of attachment.

As used herein, the following terms for substituent groups refer to the formulae given below:
“alcohol” —R³—OH
“amido” —R³—C(O)N(R⁶)R⁶
“amidosulfonate” —R³—C(O)N(R⁶)R⁴—SO₃Z
“benzyl” —CH₂—C₆H₅
“carboxylate” —R³—C(O)O—Z or —R³—O—C(O)—Z
“ether” —R³—(O—R⁵)ₚ—O—R⁵
“ether carboxylate” —R³—O—R⁴—C(O)O—Z or —R³—O—R⁴—O—C(O)—Z
“ether sulfonate” —R³—O—R⁴—SO₃Z
“ester sulfonate” —R³—O—C(O)—R⁴—SO₃Z
“sulfonimide” —R³—SO₂—NH—SO₂—R⁵
“urethane” —R³—O—C(O)—N(R⁶)₂
where all “R” groups are the same or different at each occurrence and:
   R³ is a single bond or an alkylene group
   R⁴ is an alkylene group
   R⁵ is an alkyl group
   R⁶ is hydrogen, deuterium or an alkyl group
   p is 0 or an integer from 1 to 20
   Z is H, D, alkali metal, alkaline earth metal,
   N(R⁵)₄ or R⁵
      In any of the above groups, one or more H may be replaced by D. Any of the above groups may further be unsubstituted or substituted, and any group may have F substituted for one or more hydrogens, including perfluorinated groups. In some embodiments, the alkyl and alkylene groups have from 1-20 carbon atoms. In some embodiments, the alkyl and alkylene groups are deuterated.

In some embodiments, in the monomer, both R¹ together form —W—(CY¹Y²)ₘ—W—, where m is 2 or 3, W is O, S, Se, PO, NR⁶, Y¹ is the same or different at each occurrence and is hydrogen, deuterium or fluorine, and Y² is the same or different at each occurrence and is selected from hydrogen, deuterium, halogen, alkyl, alcohol, amidosulfonate, benzyl, carboxylate, ether, ether carboxylate, ether sulfonate, ester sulfonate, and urethane, where the Y groups may be partially or fully deuterated or partially or fully fluorinated. In some embodiments, all Y are hydrogen or deuterium.

In some embodiments, the conductive precursor monomer is 3,4-ethylenedioxythiophene (“EDOT”). In some embodiments, the conductive precursor monomer is D₄-EDOT or D₆-EDOT, shown below.

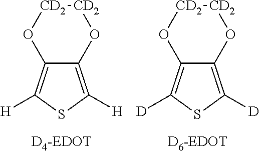

In some embodiments, the monomer has Formula I(a):

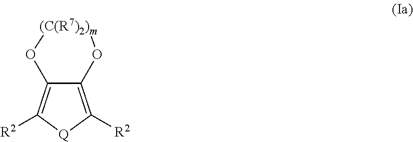

wherein:
Q is selected from the group consisting of S, Se, and Te;
R² is H or D;
R⁷ is the same or different at each occurrence and is selected from hydrogen, deuterium, alkyl, heteroalkyl, alkenyl, heteroalkenyl, alcohol, amidosulfonate, benzyl, carboxylate, ether, ether carboxylate, ether sulfonate, ester sulfonate, and urethane, with the proviso that at least one R⁷ is not hydrogen, and
m is 2 or 3.

In some embodiments of Formula I(a), m is two, one R⁷ is an alkyl group of more than 5 carbon atoms, and all other R⁷ are hydrogen or deuterium. In some embodiments of Formula I(a), at least one R⁷ group is fluorinated. In some embodiments, at least one R⁷ group has at least one fluorine substituent. In some embodiments, the R⁷ group is fully fluorinated.

In some embodiments of Formula I(a), m is 2, one R⁷ is sulfonic acid-propylene-ether-methylene and all other R⁷ are hydrogen or deuterium. In some embodiments, m is 2, one R⁷ is propyl-ether-ethylene and all other R⁷ are hydrogen or deuterium. In some embodiments, m is 2, one R⁷ is methoxy and all other R⁷ are hydrogen or deuterium. In some embodiments, one R⁷ is sulfonic acid difluoromethylene ester methylene (—CH₂—O—C(O)—CF₂—SO₃H), and all other R⁷ are hydrogen or deuterium.

In some embodiments, pyrrole monomers contemplated for use to form the electrically conductive polymer in the new composite dispersion include Formula II below.

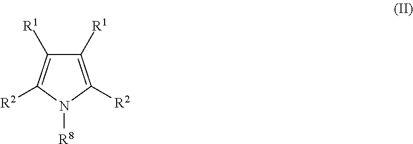

where in Formula II:
R¹ is independently selected so as to be the same or different at each occurrence and is selected from the group consisting of hydrogen, deuterium, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphoric acid, halogen, nitro, cyano, hydroxyl, epoxy, silane, siloxane, alcohol, benzyl, carboxylate, ether, amidosulfonate, ether carboxylate, ether sulfonate, ester sulfonate, urethane, and deuterated analogs thereof; or both R¹ groups together may form an alkylene or alkenylene chain completing a 3, 4, 5, 6, or 7-membered aromatic or alicyclic ring, which ring may optionally include one or more divalent nitrogen, sulfur, selenium, tellurium, or oxygen atoms;
R² is independently selected so as to be the same or different at each occurrence and is selected from the group consisting of hydrogen and deuterium; and
R⁸ is independently selected so as to be the same or different at each occurrence and is selected from hydrogen, deuterium, alkyl, alkenyl, aryl, alkanoyl, alkylthioalkyl, alkylaryl, arylalkyl, amino, epoxy, silane, siloxane, alcohol, benzyl, carboxylate, ether, ether carboxylate, ether sulfonate, ester sulfonate, urethane, and deuterated analogs thereof.

In some embodiments, R¹ is the same or different at each occurrence and is independently selected from hydrogen, deuterium, alkyl, alkenyl, alkoxy, cycloalkyl, cycloalkenyl, alcohol, benzyl, carboxylate, ether, amidosulfonate, ether carboxylate, ether sulfonate, ester sulfonate, urethane, epoxy, silane, siloxane, and alkyl substituted with one or more of sulfonic acid, carboxylic acid, acrylic acid, phosphoric acid, phosphonic acid, halogen, nitro, cyano, hydroxyl, epoxy, silane, or siloxane moieties. Any of the above groups may be deuterated.

In some embodiments, R⁸ is selected from hydrogen, alkyl, and alkyl substituted with one or more of sulfonic acid, carboxylic acid, acrylic acid, phosphoric acid, phosphonic acid, halogen, cyano, hydroxyl, epoxy, silane, or siloxane moieties.

In some embodiments, the pyrrole monomer is unsubstituted and R¹, R², and R⁸ are hydrogen. Unsubstituted non-deuterated pyrrole is abbreviated herein as “Py”. In some embodiments, R¹, R², and R⁸ are deuterium. The fully deuterated pyrrole monomer is abbreviated as “D₅-Py”. The polymer made from this monomer is abbreviated as “poly(D₅-Py)”.

In some embodiments of Formula II, both R¹ together form a 6- or 7-membered alicyclic ring, which is further substituted with a group selected from alkyl, heteroalkyl, alcohol, benzyl, carboxylate, ether, ether carboxylate, ether sulfonate, ester sulfonate, urethane, and deuterated analogs thereof. These groups can improve the solubility of the monomer and the resulting polymer. In some embodiments, both R¹ together form a 6- or 7-membered alicyclic ring, which is further substituted with an alkyl group. In some embodiments, both R¹ together form a 6- or 7-membered alicyclic ring, which is further substituted with an alkyl group having at least 1 carbon atom.

In some embodiments, both R¹ together form —O—(CY₂)ₘ—O—, where m is 2 or 3, and Y is the same or different at each occurrence and is selected from hydrogen, deuterium, alkyl, alcohol, benzyl, carboxylate, amidosulfonate, ether, ether carboxylate, ether sulfonate, ester sulfonate, urethane, and deuterated analogs thereof. In some embodiments, at least one Y group is deuterium. In some embodiments, at least one Y group is a substituent having F substituted for at least one hydrogen. In some embodiments, at least one Y group is perfluorinated.

In some embodiments, aniline monomers contemplated for use to form the electrically conductive polymer in the new composite dispersion include Formula III below.

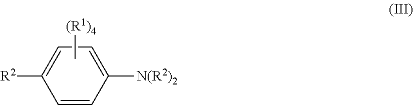

wherein:
R¹ is independently selected so as to be the same or different at each occurrence and is selected from the group consisting of hydrogen, deuterium, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphoric acid, halogen, nitro, cyano, hydroxyl, epoxy, silane, siloxane, alcohol, benzyl, carboxylate, ether, ether carboxylate, amidosulfonate, ether sulfonate, ester sulfonate, urethane, and deuterated analogs thereof; or both R¹ groups together may form an alkylene or alkenylene chain completing a 3, 4, 5, 6, or 7-membered aromatic or alicyclic ring, which ring may optionally include one or more divalent nitrogen, sulfur or oxygen atoms; and
R² is independently selected so as to be the same or different at each occurrence and is selected from the group consisting of hydrogen and deuterium.

When polymerized, the aniline monomeric unit can have Formula IV(a) or Formula IV(b) shown below, or a combination of both formulae.

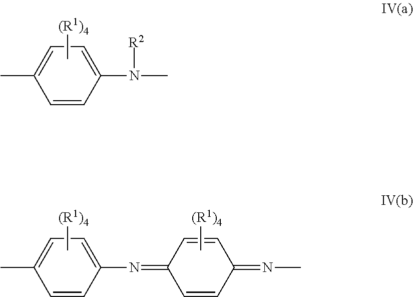

where R¹ and R² are as defined above.

In some embodiments of Formula III, the aniline monomer is unsubstituted and R¹ and R² are H or D. The non-deuterated unsubstituted aniline monomer is abbreviated herein as “ani”. In some embodiments, the monomer is D₅-ani or D₇-ani, as shown below.

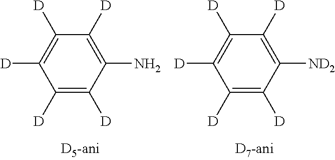

In some embodiments of Formula III, at least one R¹ is fluorinated. In some embodiments, at least one R¹ is perfluorinated.

In some embodiments, fused polycyclic heteroaromatic monomers contemplated for use to form the electrically conductive polymer in the new composite dispersion have two or more fused aromatic rings, at least one of which is heteroaromatic. In some embodiments, the fused polycyclic heteroaromatic monomer has Formula V:

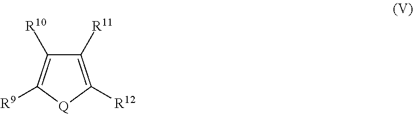

wherein:
Q is S, Se, Te, or NR⁶;
R⁶ is hydrogen, deuterium or alkyl;
R⁹, R¹⁰, R¹¹, and R¹² are independently selected so as to be the same or different at each occurrence and are selected from hydrogen, alkyl, alkenyl, alkoxy, alkanoyl, alkylthio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphoric acid, halogen, nitro, nitrile, cyano, hydroxyl, epoxy, silane, siloxane, alcohol, benzyl, carboxylate, ether, ether carboxylate, amidosulfonate, ether sulfonate, ester sulfonate, and urethane; and
at least one of R⁹ and R¹⁰, R¹⁰ and R¹¹, and R¹¹ and R¹² together form an alkenylene chain completing a 5 or 6-membered aromatic ring, which ring may optionally include one or more divalent nitrogen, sulfur, selenium, tellurium, or oxygen atoms.

In some embodiments, the fused polycyclic heteroaromatic monomer has a formula selected from the group consisting of Formula V(a), V(b), V(c), V(d), V(e), V(f), V(g), V(h), V(i), V(j), and V(k):

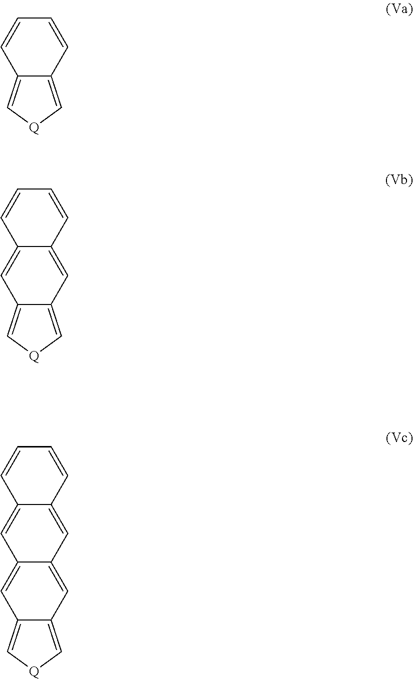

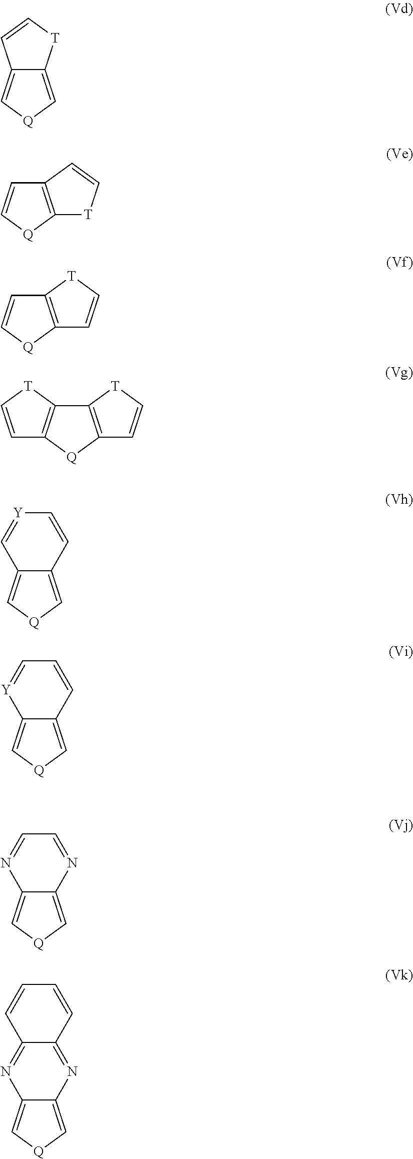

wherein:
Q is S, Se, Te, NH, or ND; and
T is the same or different at each occurrence and is selected from S, NR⁶, O, SiR⁶₂, Se, Te, and PR⁶;
Y is N; and
R⁶ is H, D, or alkyl
   The fused polycyclic heteroaromatic monomers may be further substituted with groups selected from alkyl, heteroalkyl, alcohol, benzyl, carboxylate, ether, ether carboxylate, ether sulfonate, ester sulfonate, urethane, and deuterated analogs thereof. In some embodiments, the substituent groups fully deuterated. In some embodiments, the substituent groups are fluorinated. In some embodiments, the substituent groups are fully fluorinated.

In some embodiments, the fused polycyclic heteroaromatic monomer is a thieno(thiophene) or deuterated analog thereof. The non-deuterated compounds have been discussed in, for example, Macromolecules, 34, 5746-5747 (2001); and Macromolecules, 35, 7281-7286 (2002). In some embodiments, the thieno(thiophene) is selected from thieno(2,3-b)thiophene, thieno(3,2-b)thiophene, and thieno(3,4-b)thiophene, each of which can have 0-4 deuterium atoms. In some embodiments, the thieno(thiophene) monomer is further substituted with at least one group selected from alkyl, heteroalkyl, alcohol, benzyl, carboxylate, ether, ether carboxylate, ether sulfonate, ester sulfonate, urethane, and deuterated analogs thereof. In some embodiments, the substituent groups are fully deuterated. In some embodiments, the substituents groups are fluorinated. In some embodiments, the substituent groups are fully fluorinated.

In some embodiments, polycyclic heteroaromatic monomers contemplated for use to form the polymer in the new composite dispersion include Formula VI:

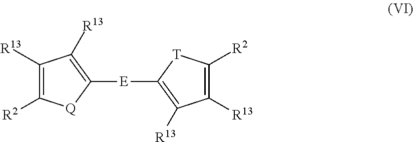

wherein:

Q is S, Se, Te, or NR⁶;

T is selected from S, NR⁶, O, SiR⁶₂, Se, Te, and PR⁶;

E is selected from alkenylene, arylene, and heteroarylene;

R² is hydrogen or deuterium;

R⁶ is hydrogen, deuterium or alkyl;

R¹³ is the same or different at each occurrence and is selected from hydrogen, deuterium, alkyl, alkenyl, alkoxy, alkanoyl, alkylthio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphoric acid, halogen, nitro, nitrile, cyano, hydroxyl, epoxy, silane, siloxane, alcohol, benzyl, carboxylate, ether, ether carboxylate, amidosulfonate, ether sulfonate, ester sulfonate, urethane, and deuterated analogs thereof; or both R¹³ groups together may form an alkylene or alkenylene chain completing a 3, 4, 5, 6, or 7-membered aromatic or alicyclic ring, which ring may optionally include one or more divalent nitrogen, sulfur, selenium, tellurium, or oxygen atoms.

In some embodiments, the electrically conductive polymer is a copolymer of a precursor monomer and at least one second monomer. Any type of second monomer can be used, so long as it does not detrimentally affect the desired properties of the copolymer. In some embodiments, the second monomer includes no more than 50% of the polymer, based on the total number of monomer units. In some embodiments, the second monomer includes no more than 30%, based on the total number of monomer units. In some embodiments, the second monomer includes no more than 10%, based on the total number of monomer units.

Exemplary types of second monomers include, but are not limited to, alkenyl, alkynyl, arylene, heteroarylene, and deuterated analogs thereof. Examples of second monomers include, but are not limited to, fluorene, oxadiazole, thiadiazole, benzothiadiazole, phenylenevinylene, phenyleneethynylene, pyridine, diazines, triazines, and deuterated analogs thereof, all of which may be further substituted.

In some embodiments, the copolymers are made by first forming an intermediate precursor monomer having the structure A-B-C, where A and C represent precursor monomers, which can be the same or different, and B represents a second monomer. The A-B-C intermediate precursor monomer can be prepared using standard synthetic organic techniques, such as Yamamoto, Stille, Grignard metathesis, Suzuki, and Negishi couplings. The copolymer is then formed by oxidative polymerization of the intermediate precursor monomer alone, or with one or more additional precursor monomers.

In some embodiments, the electrically conductive polymer is selected from the group consisting of a polythiophene, a polyaniline, a polypyrrole, a polymeric fused polycyclic heteroaromatic, a poly(aminoindole), a deuterated analog thereof, a copolymer thereof, and combinations thereof.

In some embodiments, the electrically conductive polymer is selected from the group consisting of poly(EDOT), polypyrrole, polyaniline, poly(4-aminoindole), poly(7-aminoindole), poly(thieno(2,3-b)thiophene), poly(thieno(3,2-b)thiophene), poly(thieno(3,4-b)thiophene), and deuterated analogs thereof.

### 2. Highly-Fluorinated Acid Polymer

The highly-fluorinated acid polymer (“HFAP”) is any polymer that is highly-fluorinated and has acidic groups. The acidic groups supply an ionizable proton, H⁺, or deuteron, D⁺. In some embodiments, the acidic group has a pKa of less than 3. In some embodiments, the acidic group has a pKa of less than 0. In some embodiments, the acidic group has a pKa of less than −5. The acidic group can be attached directly to the polymer backbone, or it can be attached to side chains on the polymer backbone. Examples of acidic groups include, but are not limited to, carboxylic acid groups, sulfonic acid groups, sulfonimide groups, phosphoric acid groups, phosphoric acid groups, and combinations thereof. The acidic groups can all be the same, or the polymer may have more than one type of acidic group. In some embodiments, the acidic groups are selected from the group consisting of sulfonic acid groups, sulfonimide groups, and combinations thereof.

In some embodiments, the HFAP is a deutero-acid with an acidic deuteron.

In some embodiments, the HFAP is at least 95% fluorinated; in some embodiments, fully-fluorinated. In some embodiments, when the HFAP is not fully-fluorinated, the non-fluorinated sites are deuterated so that there are no hydrogens. In some embodiments, the HFAP is fully fluorinated and is a deutero-acid with an acidic deuteron.

In some embodiments, the HFAP is water-soluble. In some embodiments, the HFAP is dispersible in water. In some embodiments, the HFAP is organic solvent wettable. The term “organic solvent wettable” refers to a material which, when formed into a film, possesses a contact angle no greater than 60° C. with organic solvents. In some embodiments, wettable materials form films which are wettable by phenylhexane with a contact angle no greater than 55°. The methods for measuring contact angles are well known. In some embodiments, the wettable material can be made from a polymeric acid that, by itself is non-wettable, but with selective additives it can be made wettable.

Examples of suitable polymeric backbones include, but are not limited to, polyolefins, polyacrylates, polymethacrylates, polyimides, polyamides, polyaramids, polyacrylamides, polystyrenes, copolymers thereof, and deuterated analogs thereof, all of which are highly-fluorinated; in some embodiments, fully-fluorinated.

In some embodiments, the acidic groups are sulfonic acid groups or sulfonimide groups. A sulfonimide group has the formula:

—SO₂—NH—SO₂—R

where R is an alkyl group. A deutero-sulfonimide group has the formula:

—SO₂—ND-SO₂—R

where R is an alkyl group.

In some embodiments, the acidic groups are on a fluorinated side chain. In some embodiments, the fluorinated side chains are selected from alkyl groups, alkoxy groups, amido groups, ether groups, and combinations thereof, all of which are fully fluorinated.

In some embodiments, the HFAP has a highly-fluorinated olefin backbone, with pendant highly-fluorinated alkyl sulfonate, highly-fluorinated ether sulfonate, highly-fluorinated ester sulfonate, or highly-fluorinated ether sulfonimide groups. In some embodiments, the HFAP is a perfluoroolefin having perfluoro-ether-sulfonic acid side chains. In some embodiments, the polymer is a copolymer of 1,1-difluoroethylene and 2-(1,1-difluoro-2-(trifluoromethyl)allyloxy)-1,1,2,2-tetrafluoroethanesulfonic acid. In some embodiments, the polymer is a copolymer of ethylene and 2-(2-(1,2,2-trifluorovinyloxy)-1,1,2,3,3,3-hexafluoropropoxy)-1,1,2,2-tetrafluoroethanesulfonic acid. These copolymers can be made as the corresponding sulfonyl fluoride polymer and then can be converted to the sulfonic acid form.

In some embodiments, the HFAP is homopolymer or copolymer of a fluorinated and partially sulfonated poly(arylene ether sulfone). The copolymer can be a block copolymer.

In some embodiments, the HFAP is a sulfonimide polymer having Formula IX:

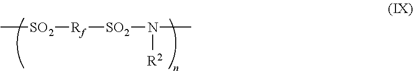

where:
R² is H or D;
R_{f} is selected from highly-fluorinated alkylene, highly-fluorinated heteroalkylene, highly-fluorinated arylene, and highly-fluorinated heteroarylene, which may be substituted with one or more ether oxygens; and
n is at least 4.
   In some embodiments of Formula IX, R_{f} is a perfluoroalkyl group. In some embodiments, R_{f} is a perfluorobutyl group. In some embodiments, R_{f} contains ether oxygens.
   In some embodiments n is greater than 10.

In some embodiments, the HFAP includes a highly-fluorinated polymer backbone and a side chain having Formula X:

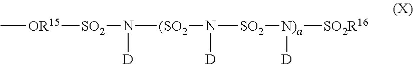

where:
R¹⁵ is a highly-fluorinated alkylene group or a highly-fluorinated heteroalkylene group;
R¹⁶ is a highly-fluorinated alkyl or a highly-fluorinated aryl group; and
a is 0 or an integer from 1 to 4.

In some embodiments, the HFAP has Formula XI:

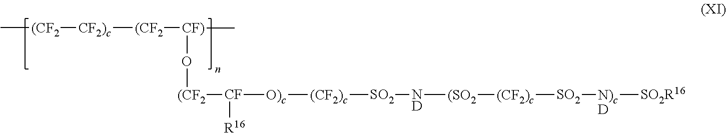

where:
R¹⁶ is a highly-fluorinated alkyl or a highly-fluorinated aryl group;
c is independently 0 or an integer from 1 to 3; and
n is at least 4.

The synthesis of non-deuterated analogs of the HFAPs has been described in, for example, A. Feiring et al., J. Fluorine Chemistry 2000, 105, 129-135; A. Feiring et al., Macromolecules 2000, 33, 9262-9271; D. D. Desmarteau, J. Fluorine Chem. 1995, 72, 203-208; A. J. Appleby et al., J. Electrochem. Soc. 1993, 140(1), 109-111; and Desmarteau, U.S. Pat. No. 5,463,005.

In some embodiments, the HFAP also includes a repeat unit derived from at least one highly-fluorinated ethylenically unsaturated compound. The perfluoroolefin includes 2 to 20 carbon atoms. Representative perfluoroolefins include, but are not limited to, tetrafluoroethylene, hexafluoropropylene, perfluoro-(2,2-dimethyl-1,3-dioxole), perfluoro-(2-methylene-4-methyl-1,3-dioxolane), CF₂═CFO(CF₂)ₜCF═CF₂, where t is 1 or 2, and R_{f}″OCF═CF₂ wherein R_{f}″ is a saturated perfluoroalkyl group of from 1 to about ten carbon atoms. In some embodiments, the comonomer is tetrafluoroethylene.

In some embodiments, the HFAP is a colloid-forming polymeric acid. As used herein, the term “colloid-forming” refers to materials which are insoluble in water, and form colloids when dispersed into an aqueous medium. The colloid-forming polymeric acids typically have a molecular weight in the range of about 10,000 to about 4,000,000. In some embodiments, the polymeric acids have a molecular weight of about 100,000 to about 2,000,000. Colloid particle size typically ranges from 2 nanometers (nm) to about 140 nm, for example. In some embodiments, the colloids have a particle size of 2 nm to about 30 nm. Any highly-fluorinated colloid-forming polymeric material having acidic protons can be used. Some of the polymers described hereinabove may be formed in non-acid form, e.g., as salts, esters, or sulfonyl fluorides. They will be converted to the acid form for the preparation of conductive compositions, described below.

In some embodiments, HFAP include a highly-fluorinated carbon backbone and side chains represented by the formula

—(O—CF₂CFR_{f}³)ₐ—O—CF₂CFR_{f}⁴SO₃E⁵

wherein R_{f}³ and R_{f}⁴ are independently selected from F, Cl or a highly-fluorinated alkyl group having 1 to 10 carbon atoms, a=0, 1 or 2, and E⁵ is H, D or a cation. In some cases E⁵ can be a cation such as Li, Na, or K, and be converted to the acid form.

In some embodiments, the HFAP can be the polymers disclosed in U.S. Pat. No. 3,282,875 and in U.S. Pat. Nos. 4,358,545 and 4,940,525. In some embodiments, the HFAP includes a perfluorocarbon backbone and the side chain represented by the formula

—O—CF₂CF(CF₃)—O—CF₂CF₂SO₃E⁵

where E⁵ is as defined above. HFAPs of this type are disclosed in U.S. Pat. No. 3,282,875 and can be made by copolymerization of tetrafluoroethylene (TFE) and the perfluorinated vinyl ether CF₂═CF—O—CF₂CF(CF₃)—O—CF₂CF₂SO₂F, perfluoro(3,6-dioxa-4-methyl-7-octenesulfonyl fluoride) (PDMOF), followed by conversion to sulfonate groups by hydrolysis of the sulfonyl fluoride groups and ion exchanged as necessary to convert them to the desired ionic form. An example of a polymer of the type disclosed in U.S. Pat. Nos. 4,358,545 and 4,940,525 has the side chain —O—CF₂CF₂SO₃E⁵, wherein E⁵ is as defined above. This polymer can be made by copolymerization of tetrafluoroethylene (TFE) and the perfluorinated vinyl ether CF₂═CF—O—CF₂CF₂SO₂F, perfluoro(3-oxa-4-pentenesulfonyl fluoride) (POPF), followed by hydrolysis and further ion exchange as necessary.

In some embodiments, the perfluorinated acid polymer is a copolymer of TFE (tetrafluoroethylene) and PSEPVE (perfluoro-3,6-dioxa-4-methyl-7-octenesulfonic acid, or the deuterated analog in which the acid proton has been exchanged for a deuteron. These materials are abbreviated as “poly(TFE-PSEPVE)” and “D-poly(TFE-PSEPVE)”, respectively.

One type of HFAP is available commercially as aqueous Nafion® dispersions, from E. I. du Pont de Nemours and Company (Wilmington, Del.).

The deutero-acid can be made from the protonic HFAP by isolating the solid acid material and treating in D₂O at an elevated temperature and pressure. In some embodiments, the solid HFAP is heated in D₂O to a temperature between 100 and 300° C. in a closed, pressure vessel.

### 3. Non-Fluorinated Polymeric Acid

Any non-fluorinated polymeric acid that is capable of doping the electrically conductive polymer can be used. Examples of acidic groups include, but are not limited to, carboxylic acid groups, sulfonic acid groups, sulfonimide groups, phosphoric acid groups, phosphoric acid groups, deuterated analogs thereof, and combinations thereof. The acidic groups can all be the same, or the polymer may have more than one type of acidic group.

In some embodiments, the acid is a non-fluorinated polymeric sulfonic acid. Some non-limiting examples of the acids are poly(styrenesulfonic acid) (“PSSA”), poly(2-acrylamido-2-methyl-1-propanesulfonic acid) (“PAAMPSA”), deuterated analogs thereof, and mixtures thereof.

### 4. Nanoparticles

The nanoparticles contemplated for use in the hole injection composition are either inorganic or organic. The nanoparticles have a variety of shapes and sizes and mixtures of shapes and sizes. In some embodiments, the nanoparticles are substantially spherical. In some embodiments, the nanoparticles are substantially elongated such as metal nanowires. In some embodiments, the aspect ratio of elongated nanoparticles is greater than 1 to 100. Aspect ratio is defined as ratio of particle width to particle length. For elongated particles, the “particle size” is considered to be the particle width. In some embodiments, the nano-particles have an irregular geometry. For irregularly-shaped particles, the “particle size” is considered to be size of the smallest screen opening through which the particle will pass.

Organic nanoparticles contemplated for use in the hole injection composition include polymeric acid colloid-particles, carbon nanoparticles, colloidal sulfonic acids (such as perfluoroethylene sulfonates, and the like), colloidal polyacrylates, colloidal polyphosphonates, colloidal polyphosphates, carbon nanotubes, carbon nano-particles, graphitized carbon nanoparticles, graphitized carbon nano-fibers, piezoelectric polymers, pyroelectric polymers, ferroelectric polymers, photoconductive polymers and mixtures thereof.

Inorganic nanoparticles contemplated for use in the hole injection composition can be insulative or semiconductive and include metallic nanoparticles, metal nanowires, electrically semiconductive metal oxides or insulating metal oxides, metal sulfides, piezoelectric, pyroelectric, or ferroelectric oxide nanoparticles, photoconductive oxide nanoparticles, and mixtures thereof.

Examples of electrically insulative oxides include, but are not limited to, silicon oxide, titanium oxides, zirconium oxide, molybdenum trioxide, vanadium oxide, aluminum oxide, zinc oxide, samarium oxide, yttrium oxide, cesium oxide, cupric oxide, stannic oxide, antimony oxide, tantalum oxides, and the like. Combinations of two or more oxide nanoparticles can be used. In some embodiments, the electrically insulative oxide nanoparticles are selected from the group consisting of silicon dioxide, titanium dioxide, and combinations thereof.

The semiconductive metal oxides are generally mixed oxides, having two or more different cations. Suitable materials include the mixed oxides of the Group 2 elements, the Group 11 elements, the elements in Groups 4, 5, and 6, the Group 8-10 transition elements, and mixed oxides of Groups 12, 13, 14 and 15 elements. In some embodiments, semiconductive metal oxides can be mixed valence metal oxides or non-stoichiometric metal oxides.

Examples of semiconductive metal oxides include, but are not limited to, indium-tin-oxide, doped zinc oxides, gallium-indium-tin oxide, zinc-indium-tin oxides, zinc-doped antimony oxides, zinc antimonates, tin-doped zinc antimonates, oxygen deficient molybdenum trioxide, vanadium pentoxide, and the like. In some embodiments, mixtures of metal oxides are used.

Examples of metal sulfides include cadmium sulfide, copper sulfide, lead sulfide, mercury sulfide, indium sulfide, silver sulfide, cobalt sulfide, nickel sulfide, and molybdenum sulfide. Mixed metal sulfides such as Ni/Cd sulfides, Co/Cd sulfides, Cd/In sulfides, and Pd—Co—Pd sulfides may be used.

In some embodiments, the metal nanoparticles may contain both sulfur and oxygen. In some embodiments, combinations of metal nanoparticles are used.

Metal oxide nanoparticles can be made by reactive sputtering of metal in the presence of oxygen, evaporation of selected oxide, and multi-component oxides, or by vapor-phase hydrolysis of inorganic compounds, for example silicon tetrachloride. It can also be produced by sol-gel chemistry using hydrolyzable metal compounds, particularly alkoxides of various elements, to react with either by hydrolysis and polycondensation to form multi-component and multi-dimensional network oxides.

Metal sulfide nanoparticles can be obtained by various chemical and physical methods. Some examples of physical methods are vapor deposition, lithographic processes and molecular beam epitaxy (MBE) of metal sulfides such as cadmium sulfide, (CdS), lead sulfide (PbS), zinc sulfide (ZnS), silver sulfide (Ag₂S), molybdenum sulfide (MoS₂) etc. Chemical methods for the preparation of metal sulfide nanoparticles are based on the reaction of metal ions in solution either with H₂S gas or Na₂S in aqueous medium.

In some embodiments, the nanoparticles are selected from the group consisting of carbon fullerenes, nanotubes, graphene nanoparticles, and combinations thereof. Examples of fullerenes include C60, C60-PCMB, and C70, as well as C84 and higher fullerenes. Any of the fullerenes may be derivatized with a (3-methoxycarbonyl)-propyl-1-phenyl group (“PCBM”), such as C70-PCBM, C84-PCBM, and higher analogs. Combinations of fullerenes can be used. The carbon nanotubes have a cylindrical shape and can be single-walled or multi-walled.

In some embodiments, the nano-particles are surface-treated with a coupling agent to be compatible with the aqueous electrically conducting polymers. The class of surface modifiers includes, but not limited to silanes, titanates, zirconates, aluminates and polymeric dispersants. The surface modifiers contain chemical functionality, examples of which include, but are not limited to, nitrile, amino, cyano, alkyl amino, alkyl, aryl, alkenyl, alkoxy, aryloxy, sulfonic acid, acrylic acid, phosphoric acid, and alkali salts of the above acids, acrylate, sulfonates, amidosulfonate, ether, ether sulfonate, estersulfonate, alkylthio, and arylthio.

The nanoparticles, can be present at a concentration of up to about 80% by weight, based on the total weight of the hole injection composition. In some embodiments, the nanoparticles are present at a concentration of 20-40% by weight, based on the total weight of the hole injection composition. In some embodiments, the nanoparticles are present at a concentration of 40-80% by weight, based on the total weight of the hole injection composition; in some embodiments, 50-70% by weight.

### 5. Optional Additives

In some embodiments, optional additives are present in the hole injection composition. Examples of types of materials which can be added include, but are not limited to polymers, dyes, coating aids, organic and inorganic conductive inks and pastes, charge transport materials, crosslinking agents, and combinations thereof. The additives should be materials that are soluble or dispersible in the liquid medium and can be simple molecules or polymers.

The amount of optional additive, when present, is generally in the range of about 1% to about 12% by weight, based on the total weight of the hole injection composition.

### 6. Preparation of Hole Injection Materials

(a) Conductive Polymer Doped with Highly-Fluorinated Acid Polymer

The conductive polymer doped with a highly-fluorinated acid polymer (“HFAP”) is formed in some embodiments by oxidative polymerization of the precursor monomer or monomers in the presence of the HFAP in an aqueous medium. This has been described in published U.S. patent applications 2004/0102577, 2004/0127637, and 2005/0205860. The preparation of deuterated analogs has been described in published U.S. patent application 2011/0147719.

In some embodiments, the oxidative polymerization is carried out in a homogeneous aqueous solution. Oxidizing agents such as ammonium persulfate, sodium persulfate, potassium persulfate, and the like, can be used. A catalyst, such as ferric chloride, or ferric sulfate may also be present. The resulting polymerized product will be a solution, dispersion, or emulsion of the conductive copolymer doped with the fluorinated acid polymer.

In some embodiments, a co-dispersing liquid is added after polymerization. Examples of suitable liquids include, but are not limited to, ethylene glycol, propylene glycol, dimethylsulfoxide, dimethylacetamide, low molecular weight poly(ethylene glycol), N-methylpyrrolidone, isopropanol, n-propanol, 1-methoxy-2-propanol, propylene glycol propyl ether, propylene glycol methyl ether, propylene glycol mono-methyl ether acetate, dipropyleneglycol methyl ether, deuterated analogs thereof, and mixtures thereof. The co-dispersing liquid can be present in an amount up to about 60% by weight, based on the total weight of solids plus liquid.

The molar ratio of oxidizer to total precursor monomer is generally in the range of about 0.1 to about 3.0. for example, about 0.4 to about 1.5. The molar ratio of fluorinated acid polymer to total precursor monomer is generally in the range of about 0.2 to about 10. In some embodiments, the ratio is in the range of about 1 to about 5. The overall solid content is generally in the range of about 0.5% to about 12% in weight percentage; in some embodiments, in the range of about 2% to about 6%. The reaction temperature is generally in the range of about 4° C. to about 50° C.; In some embodiments about 20° C. to about 35° C. The reaction time is generally in the range of about 1 to about 30 hours.

In some embodiments, the pH is increased either prior to or after the addition of any optional additives. The pH can be adjusted by treatment with cation exchange resins and/or base resins. In some embodiments, the pH is adjusted by the addition of a base solution. Cations for the base can be, but are not limited to, alkali metal, alkaline earth metal, ammonium, and alkylammonium. In some embodiments, alkali metal is preferred over alkaline earth metal cations.

Films can be made from the compositions described above using any liquid deposition technique, including continuous and discontinuous techniques. Continuous deposition techniques, include, but are not limited to, spin coating, gravure coating, curtain coating, dip coating, slot-die coating, spray coating, and continuous nozzle coating. Discontinuous deposition techniques include, but are not limited to, ink jet printing, gravure printing, and screen printing. The films thus formed are continuous, smooth and relatively transparent.

(b) Electrically Conductive Polymer Doped with Non-Fluorinated Polymeric Acid

The doped electrically conductive polymer can be formed by oxidative polymerization of the precursor monomer in the presence of the non-fluorinated polymeric acid in water. Oxidative polymerization of such monomers is well known. Oxidants such as sodium or potassium persulfate may be used. In some cases a catalyst, such as ferric sulfate can also be used. The resulting product is a dispersion of the electrically conductive polymer doped with the non-fluorinated polymeric acid in water.

In some embodiments, a co-dispersing liquid is added after polymerization, as described above in (a).

The amount of non-fluorinated polymeric acid present is generally in excess of that required to counterbalance the charge on the conducting polymer. In some embodiments, the ratio of acid equivalents of non-fluorinated polymeric acid to molar equivalents of conducting polymer is in the range of 1-5.

The hole injection material is prepared by first forming the doped electrically conductive polymer and then adding the HFAP and optional additives in any order. The ratio of acid equivalent of HFAP to acid equivalent of non-fluorinated doping acid is at least 0.1 to about 4; in some embodiments, to about 2.

The preparation of the deuterated analog has been described in published U.S. patent application 2011/0147719.

### (c) Nanoparticles

When nanoparticles are present, in some embodiments the hole injection composition is prepared by first forming the doped conductive polymer as in (a) or (b) above, and then adding the nanoparticles. The nanoparticles can be added as a solid to the aqueous dispersion of the conductive polymer ((a) or (b)), or can first be dispersed in a liquid and then added to the conductive polymer dispersion.

### B. Hole Transport Composition

Examples of hole transport materials have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules include, but are not limited to, 4,4′,4″-tris(N,N-diphenyl-amino)-triphenylamine (TDATA); 4,4′,4″-tris(N-3-methylphenyl-N-phenyl-amino)-triphenylamine (MTDATA); N,N′-diphenyl-N,N′-bis(3-methylphenyl)-[1,1′-biphenyl]-4,4′-diamine (TPD); 1,1-bis[(di-4-tolylamino) phenyl]cyclohexane (TAPC); N,N′-bis(4-methylphenyl)-N,N′-bis(4-ethylphenyl)-[1,1′-(3,3′-dimethyl)biphenyl]-4,4′-diamine (ETPD); tetrakis-(3-methylphenyl)-N,N,N′,N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl]pyrazoline (PPR or DEASP); 1,2-trans-bis(9H-carbazol-9-yl)cyclobutane (DCZB); N,N,N′,N′-tetrakis(4-methylphenyl)-(1,1′-biphenyl)-4,4′-diamine (TTB); N,N′-bis(naphthalen-1-yl)-N,N′-bis-(phenyl)benzidine (α-NPB); and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate. In some cases, triarylamine polymers are used, especially triarylamine-fluorene copolymers. In some cases, the polymers and copolymers are crosslinkable. Examples of crosslinkable hole transport polymers can be found in, for example, published US patent application 2005-0184287 and published PCT application WO 2005/052027. In some embodiments, the hole transport layer is doped with a p-dopant, such as tetrafluorotetracyanoquinodimethane and perylene-3,4,9,10-tetracarboxylic-3,4,9,10-dianhydride.

### C. Emissive Layer

Any organic electroluminescent (“EL”) material can be used in the displays described herein, including, but not limited to, small molecule organic fluorescent compounds, fluorescent and phosphorescent metal complexes, conjugated polymers, and mixtures thereof. Examples of fluorescent compounds include, but are not limited to, pyrene, perylene, rubrene, coumarin, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. Electroluminescent emissive layers including a charge carrying host material and a metal complex have been described by Thompson et al., in U.S. Pat. No. 6,303,238, and by Burrows and Thompson in published PCT applications WO 00/70655 and WO 01/41512. Examples of conjugated polymers include, but are not limited to poly(phenylenevinylenes), polyfluorenes, poly(spirobifluorenes), polythiophenes, poly(p-phenylenes), copolymers thereof, and mixtures thereof.

### D. Electron Transport Composition

Examples of electron transport materials which can be used in the optional electron transport layer, include metal chelated oxinoid compounds, including metal quinolate derivatives such as tris(8-hydroxyquinolato)aluminum (AlQ), bis(2-methyl-8-quinolinolato)(p-phenylphenolato) aluminum (BAlq), tetrakis-(8-hydroxyquinolato)hafnium (HfQ) and tetrakis-(8-hydroxyquinolato)zirconium (ZrQ); and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthrolines such as 4,7-diphenyl-1,10-phenanthroline (DPA) and 2,9-dimethyl-4,7-diphenyl-1,10-phenanthroline (DDPA); and mixtures thereof. In some embodiments, the electron transport material is selected from the group consisting of metal quinolates and phenanthroline derivatives. In some embodiments, the electron transport layer further includes an n-dopant. N-dopant materials are well known. The n-dopants include, but are not limited to, Group 1 and 2 metals; Group 1 and 2 metal salts, such as LiF, CsF, and Cs₂CO₃; Group 1 and 2 metal organic compounds, such as Li quinolate; and molecular n-dopants, such as leuco dyes, metal complexes, such as W₂(hpp)₄ where hpp=1,3,4,6,7,8-hexahydro-2H-pyrimido-[1,2-a]-pyrimidine and cobaltocene, tetrathianaphthacene, bis(ethylenedithio)tetrathiafulvalene, heterocyclic radicals or diradicals, and the dimers, oligomers, polymers, dispiro compounds and polycycles of heterocyclic radical or diradicals.

### Cathode and Electron Injection Layer

The cathode is an electrode that is particularly efficient for injecting electrons or negative charge carriers. The cathode can be any metal or nonmetal having a lower work function than the anode. Materials for the cathode can be selected from alkali metals of Group 1 (e.g., Li, Cs), the Group 2 (alkaline earth) metals, the Group 12 metals, including the rare earth elements and lanthanides, and the actinides. Materials such as aluminum, indium, calcium, barium, samarium and magnesium, as well as combinations, can be used. Li-containing organometallic compounds, LiF, Li₂O, Cs-containing organometallic compounds, CsF, Cs₂O, and CS₂CO₃ can also be deposited between the organic layer and the cathode layer to lower the operating voltage. This layer may be referred to as an electron injection layer.

### Other Layers

It is known to have other layers in organic electronic devices. The choice of materials for each of the component layers may be determined by balancing the positive and negative charges in the emitter layer to provide a device with high electroluminescence efficiency. It is understood that each functional layer can be made up of more than one layer.

### Device Fabrication

The device layers can be formed by any deposition technique, or combinations of techniques, including vapor deposition, liquid deposition, and thermal transfer. Substrates such as glass, plastics, and metals can be used. Conventional vapor deposition techniques can be used, such as thermal evaporation, chemical vapor deposition, and the like. The organic layers can be applied from solutions or dispersions in suitable solvents, using conventional coating or printing techniques, including but not limited to spin-coating, dip-coating, roll-to-roll techniques, ink-jet printing, continuous nozzle printing, screen-printing, gravure printing and the like.

For liquid deposition methods, a suitable solvent for a particular compound or related class of compounds can be readily determined by one skilled in the art. Suitable classes of solvents include, but are not limited to, aliphatic hydrocarbons (such as decane and hexadecane), halogenated hydrocarbons (such as methylene chloride, chloroform, chlorobenzene, and perfluoroheptane), aromatic hydrocarbons (such as non-substituted and alkyl- and alkoxy-substituted toluenes and xylenes), aromatic ethers (such as anisole and dibenzyl ether), heteroaromatics (such as pyridine) polar solvents (such as tetrahydropyran (“THP”), dimethylacetamide (“DMAC”) and N-methylpyrrolidone (“NMP”)), esters (such as ethylacetate, propylene carbonate, and methyl benzoate), alcohols and glycols (such as isopropanol and ethylene glycol), glycol ethers and derivatives (such as propylene glycol methyl ether and propylene glycol methyl ether acetate), and ketones (such as cyclopentanone and diisobutyl ketone).

In some embodiments, the device is fabricated by liquid deposition of the hole injection layer, the hole transport layer, and the emissive layer, and by vapor deposition of the anode, the electron transport layer, an electron injection layer and the cathode.

It is understood that the efficiency of devices described herein can be further improved by optimizing the other layers in the device. For example, more efficient cathodes such as Ca, Ba or LiF can be used. Shaped substrates and novel hole transport materials that result in a reduction in operating voltage or increase quantum efficiency are also applicable. Additional layers can also be added to tailor the energy levels of the various layers and facilitate electroluminescence.

### EXAMPLES

Two test samples each including a glass substrate seven hundred micrometers (700 μm) thick having a layer of a hole injection material (“HIL”) were prepared. The hole injection material was polypyrrole doped with the highly-fluorinated polymeric acid Nafion® (E. I du Pont de Nemours and Co., Wilmington, Del.). The hole injection material was made as described in published U.S. Patent Application US2005/0205860 and was deposited from an aqueous dispersion. The thickness of the hole injection layer on the first sample was fifty nanometers (50 nm). The thickness of the hole injection layer on the second sample was two hundred nanometers (200 nm).

A sacrificial layer of MoO₃ two nanometers (2 nm) in thickness was deposited on the first (50 nm HIL) sample while a sacrificial layer of MoO₃ 2.5 nanometers in thickness was deposited on the second (200 nm HIL) sample. Deposition of the MoO₃ layer in both cases was done using evaporation.

The contact angle of the surface of the first sample was measured using a goniometer with anisole as the liquid drop. The contact angle was found to be approximately four degrees)(4°).

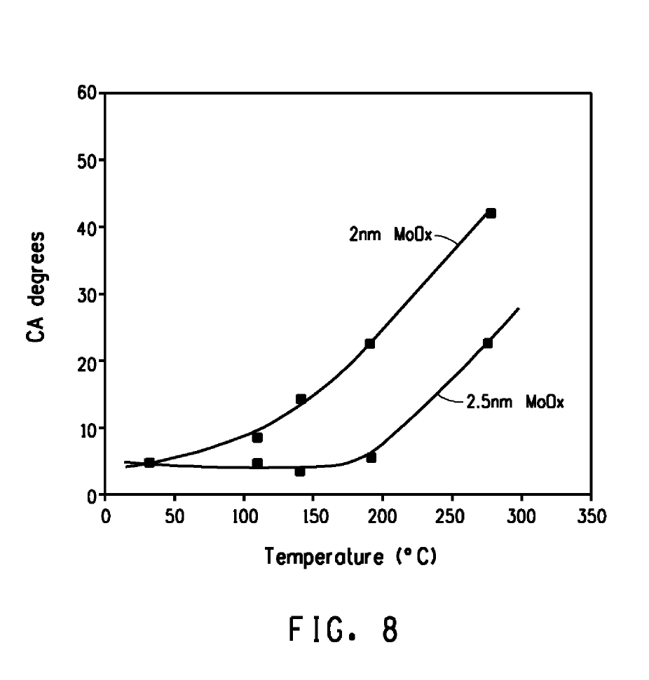

Both samples were heated in an oven with air as the atmosphere and wetting measurements were taken at various temperatures. FIG. 8 is a graphical representation of the contact angle plotted as a function of temperature.

FIG. 8 illustrates that heating causes the contact angle to increase. FIG. 8 shows that when a sacrificial layer of MoO₃ is put on the normally non-wetting surface of the hole injection material the contact angle drops, i.e., the surface becomes wetting. But when heated, the contact angle rises and above about 250° C. the surface is technically non-wetting again for the purpose of print lane containment.

A single pass of a one hundred fifty micrometer (150 μm) beam produced by a Nd:Yag laser (532 nm wavelength) set at forty-five percent (45%) of full power was made by hand across the first (50 nm HIL) sample. The energy per pulse of the laser was 0.6 mJ and the pulse width was six nanoseconds. The speed of travel was approximately 0.33 cm per second. The area irradiated in one second was one hundred fifty micrometers (150 μm) in width by approximately 0.5 centimeters in length.

Using a fine syringe one droplet of methyl benzoate were deposited on opposed sides of the laser-irradiated line. The drops were deposited away from but in proximity to the irradiated line so that the drops could spread toward the line.

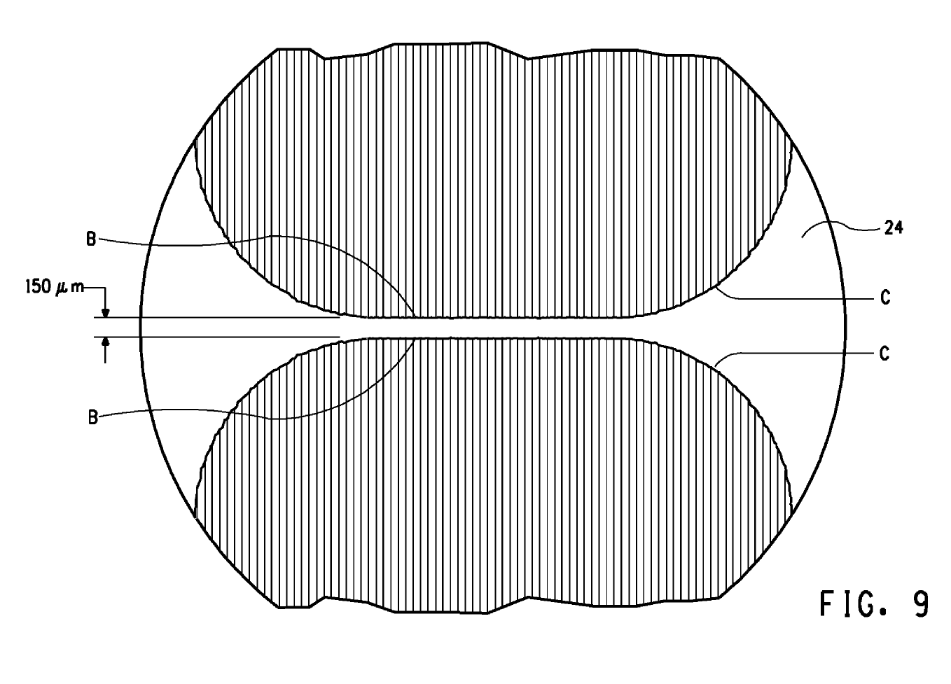

FIG. 9 is a stylized representation of a photomicrograph of the drops and irradiated line, as described. As illustrated each remained separated on one side of the laser-irradiated line. The width of the separation between drops was measured and found to correspond to the dimension of the beam (i.e., 150 μm). The boundaries B along the edges of the drops were ragged believed due to the hand scan of the laser. The drops curved from each other, as illustrated at points C, due to insufficient liquid in the drops at those points

FIG. 9 illustrates that the distance between drops in the contained section was equal to the laser line width, demonstrating that containment is very precise and not spread-out. In other words, this illustrates that the process of some embodiments of the present invention produces a high resolution display without a “fuzzy” edge that will give poor device performance.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges include each and every value within that range.

What is claimed is:

1. An electronic device comprising:
a backplane;
a layer of first organic electro-active material disposed on the backplane, some areas of the layer of first organic electro-active material having a predetermined first surface energy associated therewith while selected other areas of the layer of first organic electro-active material have a predetermined second, lower, surface energy associated therewith, the selected other areas of lower surface energy being produced by heating of these areas by exposure of the selected other areas to radiation; and
a layer of a composition comprising a second organic electro-active material disposed directly on at least some of the areas of the layer of the first organic electro-active material having the first, higher, predetermined surface energy.

2. The electronic device of claim 1 wherein the backplane has a plurality of conductive pads disposed thereon, and wherein
at least some of the conductive pads are isolated from an adjacent conductive pad by one or more boundary banks, and wherein,
the selected other areas of the first organic electro-active material having the lower predetermined surface energy register with at least some of the boundary banks on the backplane.

3. The electronic device of claim 2 wherein at least those boundary banks that register with the selected other areas of the first organic electro-active material include an additive material that has an increased optical density at the wavelength of the radiation that produced the selected other areas relative to the optical density of a boundary bank without the additive material.

4. The electronic device of claim 3, wherein the additive material is selected from the group consisting of a triarylmethane compound, an azo compound, a xanthene compound, an acridinium compound, a phenazine compound, a thiazene compound, a phthalocyanine dye, carbon black, and a metal oxide pigment.

5. The electronic device of claim 1 wherein the difference ΔCT_{(LT-NT)} in surface energy between the higher and lower areas of the surface of the first organic electro-active material as measured by contact angle determined using of anisole as a test liquid is at least twenty degrees (20°).

6. An electronic device comprising:
a backplane;
a layer of a first organic electro-active material disposed on the backplane;
a layer of sacrificial material disposed directly on the layer of the first organic electro-active material, some areas of the layer of sacrificial material having a first predetermined surface energy associated therewith while selected other areas of the layer of the sacrificial material have a second, lower, predetermined surface energy associated therewith, the selected other areas of lower surface energy being produced by exposure of the selected other areas to radiation; and
a layer of a second organic electro-active material disposed directly on substantially all of the areas of the layer of the sacrificial material having the first predetermined surface energy.

7. The electronic device of claim 6 wherein
the first organic electro-active material is an organic hole injection material comprising a conductive polymer and a fluorinated acid polymer, and wherein
the sacrificial material is non-reactive with and electrically compatible with the hole injection material.

8. The electronic device of claim 6 wherein the difference ΔCT_{(LT-NT)} in surface energy between the higher and lower areas of the surface of the first organic electro-active material as measured by contact angle determined using of anisole as a test liquid is at least twenty degrees (20°).

9. The electronic device of claim 6 wherein the sacrificial material is selected from the group consisting of an oxide of Group 3-13 metals, an electrically insulative oxide, any semiconductive metal oxide, and molybdenum nitrides.

10. A process for forming an electronic device having at least two organic electro-active materials disposed over a backplane, the process comprising:
depositing a first organic electro-active material on a backplane, the first organic electro-active material having a predetermined first surface energy associated therewith;
exposing predetermined areas of the first electro-active material to radiation from a radiation source to heat the first electro-active material to an extent sufficient to cause the exposed areas to have a second surface energy lower than the first surface energy; and
depositing a liquid composition including a second electro-active material on the first electro-active material, the liquid composition having a predetermined third surface energy associated therewith such it preferentially wets the areas of the first electro-active material having the higher first surface energy to the substantial exclusion of the areas of the first electro-active material having the lower second surface energy.

11. The process of claim 10, wherein the first electro-active material is an organic hole injection material and the second electro-active material is an organic hole transport material, further wherein the organic hole injection material comprises a conductive polymer and a fluorinated acid polymer.

12. The process of claim 10 wherein the first electro-active material includes a chemical species responsive to heating caused by incident radiation to migrate to a region near the surface of the first electro-active material thereby to alter the surface energy thereof.

13. The process of claim 10 wherein the backplane has elements of a drive and control network for the device embedded therein, and wherein
the first organic electro-active material and the material in the areas of the backplane on which it is deposited have respective predetermined energy absorbance characteristics associated therewith, and wherein
the radiation from the source has a predetermined wavelength and energy density selected such that the energy content of the radiation is absorbed within the first organic electro-active material and the material in the areas of the backplane on which it is deposited to an extent sufficient to prevent heating by the radiation from deleteriously affecting the elements of the drive and control network.

14. The process of claim 10 wherein the first organic electro-active material has a predetermined thickness dimension associated therewith, and wherein
a region of the material in the areas of the backplane on which the first organic electro-active material is deposited has a predetermined enlarged thickness dimension associated therewith, and wherein
the energy content of the radiation is substantially fully absorbed within the combined thicknesses of the first organic electro-active material and the regions of the backplane having the enlarged thickness dimension.

15. The process of claim 10, wherein the difference ΔCT_{(LT-NT)} in surface energy between an exposed area and an adjacent unexposed area as measured by contact angle determined using of anisole as a test liquid is at least twenty degrees)(20°).

16. A process for forming an electronic device having at least two organic electro-active materials disposed over a backplane, the process comprising:
depositing a first organic electro-active material on a backplane, the first organic electro-active material having a predetermined first surface energy associated therewith;
depositing a sacrificial material directly on the first organic electro-active material, the sacrificial material having a predetermined second surface energy associated therewith;
exposing predetermined areas of the sacrificial material to radiation from a radiation source to heat the sacrificial material and the first electro-active material to an extent sufficient to cause the exposed areas to have a surface energy lower than the surface energy of an adjacent unexposed area; and,
depositing a liquid composition including a second electro-active material directly on the sacrificial material, the liquid composition having a predetermined third surface energy associated therewith such it preferentially wets the areas having the higher surface energy to the substantial exclusion of the areas having the lower surface energy.

17. The process of claim 16 wherein
the first organic electro-active material is an organic hole injection material comprising a conductive polymer and a fluorinated acid polymer, and wherein
the sacrificial material is non-reactive with and electrically compatible with the hole injection material.

18. The process of claim 16 wherein the first electro-active material includes a chemical species responsive to heating caused by incident radiation to migrate to a region near the surface of the sacrificial material thereby to alter the surface energy thereof.

19. The process of claim 16 wherein the backplane has elements of a drive and control network for the device embedded therein, and wherein
the sacrificial material, the first organic electro-active material and the material in the areas of the backplane on or over which they are deposited have respective predetermined energy absorbance characteristics associated therewith, and wherein
the radiation from the source has a predetermined wavelength and energy density selected such that the energy content of the radiation is absorbed within the sacrificial material, the first organic electro-active material and the material of the backplane to an extent sufficient to prevent heating by the radiation from deleteriously affecting the elements of the drive and control network.

20. The process of claim 16 wherein the sacrificial material and the first organic electro-active material each have a predetermined thickness dimension associated therewith, and wherein
a region of the material in the areas of the backplane on which the first organic electro-active material is deposited has a predetermined enlarged thickness dimension associated therewith, and wherein
the energy content of the radiation is substantially fully absorbed within the combined thicknesses of the sacrificial material, the first organic electro-active material and the regions of the backplane having the enlarged thickness dimension.
